(19) United States
(12) Patent Application Publication
(10) Pub. No.: US 2024/0414934 A1
(43) Pub. Date: Dec. 12, 2024

(54) METHOD OF MANUFACTURING DISPLAY DEVICE, LIGHT-EMITTING ELEMENT, AND DISPLAY DEVICE

(71) Applicant: Sharp Display Technology Corporation, Kameyama, Mie (JP)

(72) Inventor: Masayuki KANEHIRO, Kameyama City, Mie (JP)

(21) Appl. No.: 18/696,941

(22) PCT Filed: Dec. 15, 2021
(86) PCT No.: PCT/JP2021/046264

§ 371 Date: Mar. 28, 2024

(51) Int. Cl. H10K 50/115; H10K 50/17; H10K 71/20

(52) U.S. Cl. CPC H10K 50/115; H10K 50/17; H10K 71/221

(57) ABSTRACT

The invention includes: a step of forming a red sacrifice layer on a hole transport layer; a step of exposing the hole transport layer by removing a part of the red sacrifice layer; a step of forming a red light-emitting layer containing red quantum dots and red ligands on the red sacrifice layer and the hole transport layer; and a step of patterning the red light-emitting layer by removing the red sacrifice layer using a red detaching solution containing red addition ligands.

### TECHNICAL FIELD

The disclosure relates to methods of manufacturing display devices and to display devices.

### BACKGROUND ART

QLEDs (quantum-dot light-emitting diodes) are becoming popular.

Patent Literature 1 discloses a method of applying and curing a coating solution, for forming a light-emitting layer, containing silane coupling agent-positioned quantum dots to form a light-emitting layer and then patterning the light-emitting layer by lift-off.

### CITATION LIST

### Patent Literature

Patent Literature 1: Japanese Unexamined Patent Application Publication No. 2009-87760

### SUMMARY

### Technical Problem

Patent Literature 1 has a primary object to provide a method of manufacturing an electroluminescent element that: includes a light-emitting layer containing quantum dots; allows for stable patterning of the light-emitting layer by lift-off; and exhibits a good life property.

The method disclosed in Patent Literature 1, however, has difficulty in injecting carriers to quantum dots because a silane coupling agent is used as the ligands positioned around the quantum dots. Patent Literature 1 witnesses emission of light at voltages as high as 10 volts.

In addition, the silane coupling agent does not readily coordinate to quantum dots. This is because the silane coupling agent would generally coordinate to hydroxy groups which are not present on the surfaces of the quantum dots. In the current context, the surfaces of the quantum dots are the surfaces of the shells if the quantum dots have a core-shell structure.

Additionally, the method disclosed in Patent Literature 1 requires hydrolysis of the silane coupling agent and for this reason could, in a high temperature process, undesirably damage the quantum dots and promote curing of the photoresist layer. Curing of the photoresist layer can lead to inappropriate lift-off of light-emitting layer.

### Solution to Problem

The disclosure, in an aspect thereof, is directed to a method of manufacturing a display device, the method including: a step of forming a first sacrifice layer on a charge functional layer; a step of exposing the charge functional layer by removing a part of the first sacrifice layer; a step of forming a first light-emitting layer containing first quantum dots and first ligands on the first sacrifice layer and the charge functional layer; and a step of patterning the first light-emitting layer by removing the first sacrifice layer using a first detaching solution containing second ligands.

### Advantageous Effects of Disclosure

The disclosure, in an aspect thereof, provides, unlike Patent Literature 1, a display device that includes a light-emitting layer containing quantum dots and that exhibits a good life property.

### BRIEF DESCRIPTION OF DRAWINGS

FIG. 1 is a schematic plan view of an exemplary structure of a display device in accordance with an embodiment of the present disclosure.

FIG. 2 is a schematic cross-sectional view of an exemplary structure of a display area shown in FIG. 1.

FIG. 3 is a schematic flow chart representing an exemplary method of manufacturing the display device in accordance with the embodiment of the present disclosure.

FIG. 4 is a schematic flow chart representing an exemplary step of forming a light-emitting layer in accordance with the embodiment of the present disclosure.

FIG. 5 is a schematic cross-sectional view of the exemplary step of forming the light-emitting layer in accordance with the embodiment of the present disclosure.

FIG. 6 is a schematic cross-sectional view of the exemplary step of forming the light-emitting layer in accordance with the embodiment of the present disclosure.

FIG. 7 is a schematic cross-sectional view of the exemplary step of forming the light-emitting layer in accordance with the embodiment of the present disclosure.

FIG. 8 is a schematic cross-sectional view of the exemplary step of forming the light-emitting layer in accordance with the embodiment of the present disclosure.

FIG. 9 is a schematic cross-sectional view of the exemplary step of forming the light-emitting layer in accordance with the embodiment of the present disclosure.

FIG. 10 is a schematic cross-sectional view of the exemplary step of forming the light-emitting layer in accordance with the embodiment of the present disclosure.

FIG. 11 is a schematic cross-sectional view of the exemplary step of forming the light-emitting layer in accordance with the embodiment of the present disclosure.

FIG. 12 is a schematic cross-sectional view of the exemplary step of forming the light-emitting layer in accordance with the embodiment of the present disclosure.

FIG. 13 is a schematic cross-sectional view of the exemplary step of forming the light-emitting layer in accordance with the embodiment of the present disclosure.

FIG. 14 is a schematic cross-sectional view of the exemplary step of forming the light-emitting layer in accordance with the embodiment of the present disclosure.

FIG. 15 is a schematic cross-sectional view of the exemplary step of forming the light-emitting layer in accordance with the embodiment of the present disclosure.

FIG. 16 is a schematic cross-sectional view of an exemplary step of forming a light-emitting layer 24 in accordance with an embodiment of the present disclosure.

FIG. 17 is a diagram showing a graph representing temporal changes in the photoluminescence intensities of display devices of examples and comparative examples of the present disclosure.

FIG. 18 is a schematic cross-sectional view of an exemplary step of forming the light-emitting layer in accordance with the embodiment of the present disclosure.

FIG. 19 is a schematic cross-sectional view of an exemplary structure of a display area of a display device in accordance with an embodiment of the present disclosure.

FIG. 20 is a schematic flow chart representing an exemplary method of manufacturing a display device 2 in accordance with an embodiment of the present disclosure.

### DESCRIPTION OF EMBODIMENTS

### Embodiment 1

Throughout the following description, expressions like “component A is in the same layer as component B” indicate that components A and B are formed in a single process or step (film formation step), expressions like “component A underlies/is below component B” indicate that component A is formed in an earlier process or step than component B, and expressions like “component A overlies/is on or above component B” indicate that component A is formed in a later process or step than component B.

### Outline of Display Device

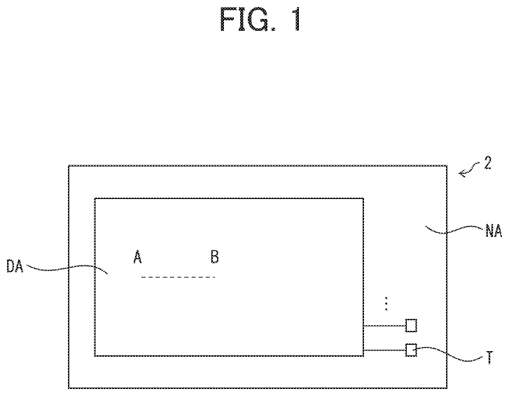

FIG. 1 is a schematic plan view of an exemplary structure of a display device 2 in accordance with an embodiment of the present disclosure.

Referring to FIG. 1, the display device 2 in accordance with the present disclosure includes: a display area DA in which a display is produced by extracting the light emitted by light-emitting elements detailed later; and a frame area NA surrounding the display area DA. The frame area NA has formed therein terminals T through which signals are fed for driving the light-emitting elements in the display device 2.

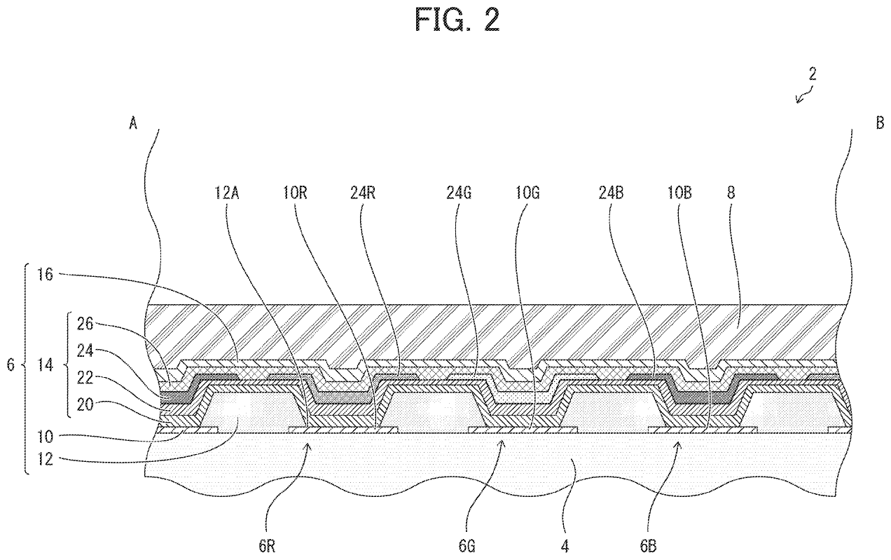

FIG. 2 is a schematic cross-sectional view of an exemplary structure of the display area DA shown in FIG. 1. FIG. 2 is an equivalent of an AB cross-sectional view of FIG. 1.

The display device 2 in accordance with the present embodiment includes a plurality of electroluminescent elements in the display area DA. FIG. 2 shows a red light-emitting element 6R, a green light-emitting element 6G, and a blue light-emitting element 6B among all the plurality of electroluminescent elements included in the display device 2. In the present disclosure, the “light-emitting element” refers to one of the red light-emitting element 6R, the green light-emitting element 6G, and the blue light-emitting element 6B unless otherwise mentioned explicitly.

Referring to FIG. 2, the display device 2 includes a substrate 4, a light-emitting element layer 6 on the substrate 4, and a sealing layer 8 covering the light-emitting element layer 6.

### Substrate

The substrate 4 includes a support substrate. The substrate 4 includes a thin film transistor layer (TFT layer) including thin film transistors (TFT's) and other circuit elements on the support substrate. The substrate 4 may further include a barrier layer and other additional structural elements. The barrier layer alleviates penetration by, for example, moisture and oxygen of the light-emitting element layer 6 from outside the support substrate.

The support substrate may be either a non-flexible substrate made of, for example, quartz or glass or a flexible substrate made of a resin film or a resin sheet. A quartz substrate and a glass substrate are preferred because of their high light-transmitting properties and high gas-blocking properties. In addition, in view of light-transmitting properties and gas-blocking properties, when the support substrate includes a resin film, the material is preferably, for example, a methacrylic resin, which is typically polyethylene methacrylate (PMMA), a polyester resin, which is typically polyethylene terephthalate (PET), polyethylene naphthalate (PEN), or polybutylene naphthalate (PBN), or a polycarbonate resin.

### Light-Emitting Element Layer

The light-emitting element layer 6 contains light-emitting elements formed therein.

The light-emitting element layer 6 in accordance with the present embodiment includes anodes 10 (first electrodes) on the substrate 4, a cathode 16 (second electrode) opposite the anodes 10, a bank 12, and an active layer 14 between the anodes 10 and the cathode 16. The active layer 14 contains a hole injection layer 20 (charge functional layer), a hole transport layer 22 (charge functional layer), a light-emitting layer 24, and an electron transport layer 26, which are provided in this order when viewed from the anodes 10. The active layer 14 may be alternatively referred to as the electroluminescence layer (EL layer).

Throughout the present disclosure, the direction from the light-emitting layer 24 in the light-emitting element layer 6 toward the substrate 4 is described as “downward” or “down,” and the direction from the light-emitting layer 24 toward the sealing layer 8 is described as “upward” or “up.”

In the current context, each light-emitting element includes one of the anodes 10 formed therein. One anode 10 is provided in each light-emitting element, that is, insularly in each subpixel, and is alternatively referred to as a pixel electrode. The anode 10 includes an anode 10R for the red light-emitting element 6R, an anode 10G for the green light-emitting element 6G, and an anode 10B for the blue light-emitting element 6B. On the other hand, the hole injection layer 20, the hole transport layer 22, the electron transport layer 26, and the cathode 16 are each provided commonly to a plurality of light-emitting elements. The cathode 16 is alternatively referred to as the common electrode.

The bank 12 may be provided individually for each light-emitting element, but preferably provided integral to a plurality of light-emitting elements to achieve high definition on the display device 2. The bank 12 is provided at least partially adjoining the anode 10, adjacent to the anode 10 at a distance, or on the anode 10 in a top view. Throughout the present disclosure, the term, “adjoin,” is used to depict objects adjacent to, and also in contact with, each other, whereas the term, “adjacent,” is used to depict not only objects in contact with each other, but also objects adjacent to each other at a distance.

The bank 12 is a protrusion formed along a peripheral portion of the light-emitting element and is not limited in function. The bank 12 may be provided on a part of the peripheral portion of the light-emitting element. The bank 12 may, either alone or in cooperation with other structural elements, perform an arbitrary function other than the function of providing a non-flat surface.

For instance, the bank 12 is preferably formed as a partition wall between adjacent light-emitting elements to provide electrical insulation between the light-emitting elements. In this structure, the bank 12 is electrically insulating, and the light-emitting element layer 6 is partitioned into the red light-emitting element 6R, the green light-emitting element 6G, and the blue light-emitting element 6B by the bank 12.

For instance, the bank 12 is preferably provided as an edge cover covering an edge of the anode 10. Specifically, the bank 12 is preferably provided at least partially either in contact with an end face of the anode 10 or on the end face of the anode 10 in a top view. The following description will focus on the structure in which the bank 12 is partially disposed on the anodes 10, with reference to drawings for simple description. Given such a description, a person skilled in the art will easily understand the structure in which the bank 12 adjoins the anodes 10 or is partially adjacent to the anodes 10.

The light-emitting layer 24 contains a red light-emitting layer 24R that emits red light, a green light-emitting layer 24G that emits green light, and a blue light-emitting layer 24B that emits blue light. The light-emitting layer 24 may be provided either individually for each light-emitting element or commonly to a plurality of light-emitting elements of the same color.

The light-emitting layer 24 is provided so as to cover at least the corresponding anode 10 exposed in an opening 12A in the bank 12. If the hole transport layer 22 comes into contact with the electron transport layer 26 above the exposed region of the anode 10 or above its vicinity, a reactive current that does not contribute to the emission of light by the light-emitting layer 24 flows through the contact site. Therefore, the light-emitting layer 24 preferably further covers a part of a side face of the bank 12 (specifically, a part that is close to the profile of the corresponding opening 12A).

Throughout the present disclosure, “blue light” refers to, for example, light that has a central emission wavelength in the wavelength range of from 400 nm to 500 nm, both inclusive. “Green light” refers to, for example, light that has a central emission wavelength in the wavelength range of from 500 nm exclusive to 600 nm inclusive. “Red light” refers to, for example, light that has a central emission wavelength in the wavelength range of from 600 nm exclusive to 780 nm inclusive.

Note that the light-emitting element layer 6 in accordance with the present embodiment is not limited to this structure and may include an additional layer between the anode 10 and the cathode 16. For example, the light-emitting element layer 6 may further include an electron injection layer between the electron transport layer 26 and the cathode 16. In addition, the light-emitting layer 24 may be capable of emitting light of two or fewer colors and may be capable of emitting light of four or more colors.

The anode 10 and the cathode 16 contain a conductive material, and either one or both of the anode 10 and the cathode 16 is/are a transparent electrode. When the display device 2 is a single-sided display, one of the electrodes (the anode 10 and the cathode 16) that is closer to the display screen is a transparent electrode, and the electrode that is farther from the display screen is a reflective electrode. When the display device 2 is a double-sided display, both the anode 10 and the cathode 16 are a transparent electrode. The transparent electrode may be made of a light-transmitting, conductive material. The reflective electrode may be made of a light-reflective, conduction material and may be a stack of a light-transmitting, conductive material and a light-reflective, conduction material.

Examples of the light-transmitting, conductive material include indium tin oxide (ITO), indium zinc oxide (IZO), tin oxide (SnO₂), and fluorine-doped tin oxide (FTO). These materials have a high transmittance to visible light and therefore improve the luminous efficiency of the light-emitting element. Examples of the light-reflective, conduction material include aluminum (Al), silver (Ag), copper (Cu), and gold (Au) and silver alloys like MgAg. These materials have a high reflectance to visible light and therefore improve the luminous efficiency of the light-emitting element. Note that the light-reflective, conduction material may be provided with such a small thickness that the material can acquire sufficient light transmittance for use as a light-transmitting, conductive material. In addition, the light-reflective, conduction material may be provided in such a form of a net of nanowires (NW's) that the material can acquire sufficient light transmittance for use as a light-transmitting, conductive material.

The anode 10 feeds holes to the light-emitting layer 24, whereas the cathode 16 feeds electrons to the light-emitting layer 24. The anode 10 is disposed opposite the cathode 16.

The hole injection layer 20 contains a hole transport material and has a function of injecting holes from the anode 10 to the hole transport layer 22 or the light-emitting layer 24. The hole transport layer 22 contains a hole transport material and has a function of transporting holes from the hole injection layer 20 or the anode 10 to the light-emitting layer 24. Note that at least one of the hole injection layer 20 and the hole transport layer 22 preferably has a function of inhibiting the transport of electrons from the light-emitting layer 24 to the anode 10.

The hole transport material may be selected in a suitable manner from materials commonly used in the field.

The organic hole transport material may be, for example, polystyrene sulfonate-doped polyethylenedioxythiophene (PEDOT: PSS), 4,4′,4″-tris(9-carbazoyl)triphenylamine (TCTA), 4,4′-bis [N-(1-naphthyl)-N-phenyl-amino]-biphenyl (NPB), zinc phthalocyanine (ZnPC), di [4-(N,N-ditolylamino)phenyl]cyclohexane (TAPC), 4,4′-bis(carbazol-9-yl) biphenyl (CBP), 2,3,6,7,10,11-hexacyano-1,4,5,8,9,12-hexaazatriphenylene (HATCN), poly(N-vinylcarbazole) (PVK), poly(2,7-(9,9-di-n-octylfluorene))-(1,4-phenylene-(4-sec-butylphenyl)imino)-1,4-phenylene (TFB), or poly(triphenylamine) derivative (Poly-TPD).

The inorganic hole transport material may be, for example, a material containing one or more compounds selected from the group consisting of metal compounds that contain any one or more of Zn, Cr, Ni, Ti, Nb, Al, Si, Mg, Ta, Hf, Zr, Y, La, Sr, and W and that also contain at least one or more of the oxygen atom, the hydroxy group, the carbon atom, and the nitrogen atom. Among these examples, the inorganic hole transport material is preferably an oxide containing any one or more of Zn, Cr, Ni, Ti, Nb, Al, Si, Mg, Ta, Hf, Zr, Y, La, and Sr. Other examples of preferred inorganic hole transport materials include CuSCN and like materials in which a CN group, a SCN group, or a SeCN group is bonded to a metal. These inorganic hole transport materials may be nanoparticles (NP's).

In the present disclosure, other metal oxides may similarly be either an oxide per se or an industrially manufactured and/or used mixture.

In the present disclosure, the term, “nanoparticles,” refers to particles with a nanoscale maximum width (under 1,000 nm). The shape of the nanoparticles needs only to satisfy this maximum width condition, is not limited in any particular manner, and is not necessarily a spherical solid (with a circular cross-section). The shape may be, for example, a polygonal cross-section, a virgulate solid, a ramal solid, a solid with a non-flat surface, or a combination of any of these shapes.

Inorganic materials are chemically more stable than organic materials and contribute to improvement of the life and reliability of products such as light-emitting elements and display devices that include light-emitting elements. Therefore, the hole injection layer 20 and the hole transport layer 22 preferably contain an inorganic hole transport material. Furthermore, the inorganic hole transport material is preferably a metal oxide and when this is the case, exhibits improved chemical stability. That inorganic materials are preferred and that metal oxides are more preferred as detailed here are equally applicable to all the elements, materials, or layers in the active layer 14. In addition, the inorganic material or the metal oxide is preferably nanoparticles. This is because the nanoparticles impart a greater surface area than the bulk form or the vapor deposition film form and in turn deliver improved electrochemical activity which could vary with the surface area.

The hole injection layer 20 preferably contains a nickel oxide as the hole transport material. This is because nickel oxides have high alkali resistance. Therefore, when an alkaline development solution is used in the patterning of the light-emitting layer 24, the degradation of the hole injection layer 20 can be alleviated.

In the present disclosure, the term, “nickel oxide,” refers to a compound containing nickel and oxygen. In other words, as an example, the nickel oxide includes not only Ni₂O₃ as an oxide per se, NiO as an oxide per se, or Ni₂O as an oxide per se, all of which have the same valency value, but also a mixture of any two or more of Ni₂O₃, NiO, and Ni₂O, which have different valency values, a mixture of any one or more of Ni₂O₃, NiO, and Ni₂O and a nickel compound other than oxides, or a mixture of any one or more of Ni₂O₃, NiO, and Ni₂O and a metal compound other than nickel compounds. In the present disclosure, the term, “nickel oxide,” may refer inclusively to mixtures manufactured and/or used industrially as a nickel oxide.

When the hole transport material used in the hole injection layer 20 is a metal oxide, a monomolecular film is preferably provided on the surface of the hole injection layer 20 (in other words, between the hole injection layer 20 and the hole transport layer 22). The monomolecular film may contain either only one species of molecules or two or more species of molecules. The monomolecular film is preferably a self-assembled monolayer (SAM).

The self-assembling molecules may include one or more species of molecules selected from R—SH, RS—SR′, R—RSCN, R—SeH, R—TeH, RSe—SeR′, R—NC, R—NCO, R—SiH₃, R—Si(CH₃)₂H, R—Si(CH₃)₃, R—COOH, dye-COOH, R—PO₃H₂, RO—PO₃H₂, R—SiX₂[X=Cl, OCH₃, OC₂H₅], R—NH₂, R—OH, [R—C(O)O]₂, R—CH═CH₂, R—C═CH, R—MgBr₂, R—Li, Ar—N₂⁺X⁻[X=Cl, OCH3, OC₂H₅], and R—BrR—CH—CH₂, where R and R′ are functional groups in the molecules.

In the current context, His hydrogen, S is sulfur, C is carbon, N is nitrogen, Si is silicon, Cl is chlorine, Se is selenium, Te is tellurium, Mg is magnesium, Br is bromine, Li is lithium, Ar is an aryl group, and X is any of Cl, OCH₃, and OC₂H₅.

The self-assembling molecules are preferably and particularly 2PACz, MeO-2PACz, and FOPA.

The electron transport layer 26 contains an electron transport material and has a function of transporting electrons from the cathode 16 to the light-emitting layer 24. The electron transport layer 26 preferably has a function of inhibiting the transport of holes from the light-emitting layer 24 to the cathode 16.

The organic electron transport material suitably used as the electron transport layer 26 may be, for example, a compound or complex with one or more nitrogen-containing hetero ring such as an oxadiazole ring, a triazole ring, a triazine ring, a quinoline ring, a phenanthroline ring, a pyrimidine ring, a pyridine ring, an imidazole ring, and a carbazole ring. Specific examples include 1,10-phenanthroline derivatives such as bathocuproine and bathophenanthroline; benzimidazole derivatives such as 1,3,5-tris(N-phenylbenzimidazol-2-yl)benzene (TPBI); metal complexes such as tris(8-quinolinolato)aluminum complexes (Alq3), bis(10-benzoquinolinolato) beryllium complexes, 8-hydroxyquinoline Al complexes, and bis(2-methyl-8-quinolinate)-4-phenyl phenorate aluminum; and 4,4′-biscarbazolebiphenyl. Other examples include aromatic phosphine compounds such as aromatic boron compounds, aromatic silane compounds, and phenyl di(1-pyrenyl) phosphine; and nitrogen-containing heterocyclic compounds such as bathophenanthroline, bathocuproine, 2,2′,2″-(1,3,5-benzenetriyl)-tris(1-phenyl-1-H-benzimidazole) (TPBI), and triazine derivatives.

The organic electron transport material suitably used as the electron transport layer 26 may alternatively be, for example, a compound with a paraphenylenevinylene backbone. Specific examples include polyparaphenylenevinylene (PPV)-based compounds such as poly(2-2′-ethyl-hexoxy)-5-methoxy-1,4-phenylenevinylene (POPh-PPV).

Furthermore, the inorganic electron transport material suitably used as the electron transport layer 26 may be, for example, an oxide containing any one or more of Zn, Ni, Cr, Mg, Li, Ti, W, Mo, In, and Ga. Among these examples, those oxides which are likely to shift toward oxygen deficiency on the basis of stoichiometric composition are preferred. Examples include zinc oxide (ZnO), magnesium zinc oxide (MgZnO), titanium oxide (TiO2), and strontium oxide (SrTiO3). These materials may be nanoparticles.

As described earlier, inorganic materials are chemically more stable than organic materials and improve the reliability of products. The electron transport layer 26 therefore preferably contains an inorganic electron transport material. Furthermore, the inorganic electron transport material is preferably a metal oxide, in which case the chemical stability increases. In addition, zinc oxide-based materials are most preferred. Additionally, the inorganic material or the metal oxide is preferably provided in the form of nanoparticles.

The transparent electrode, the hole injection layer 20, the hole transport layer 22, and the electron transport layer 26 transmit light in the wavelength range that is used in producing displays on the display device 2.

The light-emitting layer 24 is the layer in which holes from the anode 10 and electrons from the cathode 16 recombine, producing excited light-emitting matter that emits light upon falling to ground state. Applying voltage or current across the anode 10 and the cathode 16 causes the recombination in the light-emitting layer 24, which in turn produces light. The light-emitting layer 24 contains quantum dots as light-emitting matter and contains ligands coordinated to the quantum dots.

In the present disclosure, the term, “ligands,” refers to molecules or ions that can bond to quantum dots. More specifically, “ligands” may refer to not only molecules or ions that are actually bonded to quantum dots, but also molecules or ions that can bond to quantum dots, but are not actually bonded to quantum dots.

“Quantum dots” refers to dots with a maximum width of less than or equal to 100 nm. The shape of the quantum dots needs only to satisfy this maximum width condition, is not limited in any particular manner, and is not necessarily limited to a spherical solid (with a circular cross-section). The shape may be, for example, a polygonal cross-section, a virgulate solid, a ramal solid, a solid with a non-flat surface, or a combination of any of these shapes. In the present example, the quantum dots are, as an example, semiconductor fine particles with a particle size of less than or equal to 100 nm and may contain a Group II-VI semiconductor compound such as MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, or HgTe; crystals of Group III-V semiconductor compound such as GaAs, GaP, InN, InAs, InP, or InSb; and/or crystals of a Group IV semiconductor compound such as Si or Ge. In addition, the quantum dots may have, for example, a core/shell structure including these semiconductor crystals, as the core, that are overcoated with a shell material that has a large bandgap. Note that the shell does not necessarily completely cover the core and may be formed on a part of the core.

The ligands may be selected in a suitable manner from materials commonly used in the field.

Examples of organic ligands include alkyl thiol, alkyl amine, alkyl carboxylic acid, and alkylated phosphorus. Examples of inorganic ligands include halide ions such as fluoride ions, chloride ions, bromide ions, and iodide ions.

When the bank 12 is electrically insulating, the bank 12 may contain an insulating material. The bank 12 may contain, for example, a polyimide resin, an acrylic resin, a novolac resin, or a fluorene resin. The bank 12 may be formed by, for example, patterning a photosensitive resin material by photolithography. The photosensitive resin may be either of a negative type or of a positive type.

The sealing layer 8 covers the light-emitting element layer 6 to seal the light-emitting elements in the display device 2. The sealing layer 8 reduces permeation of, for example, moisture and oxygen into the light-emitting element layer 6 from outside the display device 2 through the sealing layer 8. The sealing layer 8 may have, for example, a layered structure including an inorganic sealing film made of an inorganic material and an organic sealing film made of an organic material. The inorganic sealing film is formed, for example, by CVD and includes a silicon oxide film, a silicon nitride film, a silicon oxynitride film, or a stack of any of these films. The organic sealing film is made of, for example, polyimide or a like resin material that can be provided by printing or coating technology.

### Method of Manufacturing Display Device

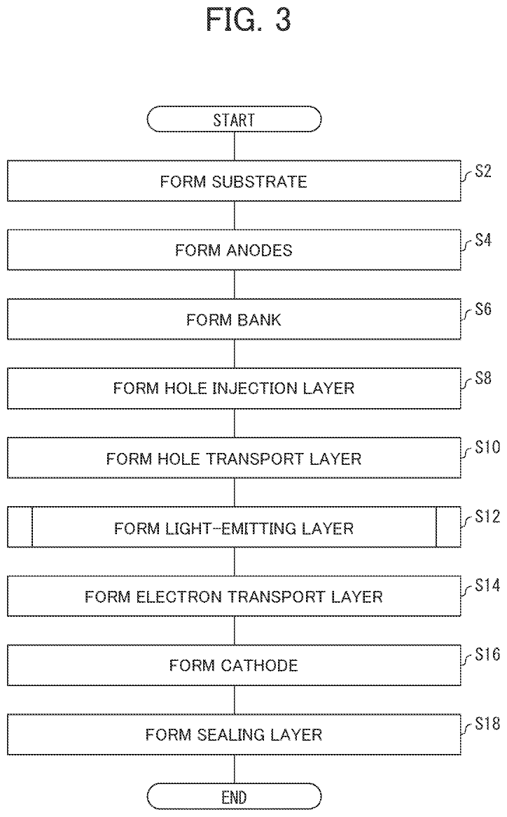

FIG. 3 is a schematic flow chart representing an exemplary method of manufacturing the display device 2 in accordance with the present embodiment.

In the method of manufacturing the display device 2 in accordance with the present embodiment, first, the substrate 4 is formed (step S2). The substrate 4 may be formed by, for example, forming a film base member on a rigid glass substrate and TFTs on this film base member and subsequently lifting the glass substrate from the film base member. This lifting of the glass substrate may be performed after the light-emitting element layer 6 and the sealing layer 8 are formed (detailed later). Alternatively, the substrate 4 may be formed by, for example, forming the TFTs directly on the rigid glass substrate.

Next, the anodes 10 are formed on the substrate 4 (step S4). The anodes 10 may be formed by, for example, forming a thin film of a metal material by, for example, sputtering and vacuum vapor deposition and subsequently patterning this thin film by dry etching or wet etching using a photoresist. Hence, the anodes 10R, the anodes 10G, and the anodes 10B are obtained in an insular manner for each subpixel on the substrate 4.

Next, the bank 12 is formed (step S6). In step S6, the bank 12 is formed by performing photolithography on a positive photosensitive resin. Specifically, a positive photosensitive resin that is a material for the bank 12 is applied to, for example, the top face of the substrate 4 and the anodes 10. Next, a photomask with transparent regions in locations corresponding to the subpixels is placed above the applied photosensitive resin, and, for example, ultraviolet light is projected through the photomask. Next, the photosensitive resin irradiated with the ultraviolet light is rinsed in a suitable development solution. Hence, the bank 12 is formed between the locations corresponding to the subpixels on the substrate 4.

Next, the hole injection layer 20 is formed (step S8). In forming the hole injection layer 20, for example, a hole transport material is dissolved in a solvent to obtain a material solution, and this material solution is applied onto the anodes 10 and the bank 12 and solidified. The hole injection layer 20 may be formed by, for example, another method such as vacuum vapor deposition or sputtering.

Next, the hole transport layer 22 is formed (step S10). In forming the hole transport layer 22, for example, a hole transport material is dissolved in a solvent to obtain a material solution, and this material solution is applied onto the hole injection layer 20 and solidified. The hole transport layer 22 may be formed by, for example, another method such as vacuum vapor deposition or sputtering.

Next, the light-emitting layer 24 is formed (step S12). The forming of the light-emitting layer 24 will be described in detail.

Next, the electron transport layer 26 is formed (step S14). The electron transport layer 26 is formed by, for example, dissolving an electron transport material in a solvent to prepare a material solution, applying this material solution onto the light-emitting layer 24 and the hole transport layer 22, and solidifying the material solution. The electron transport layer 26 may be formed by, for example, another method such as vacuum vapor deposition or sputtering.

Next, the cathode 16 is formed (step S16). The cathode 16 may be formed by, for example, forming a thin film of a metal material commonly to the subpixels by, for example, vacuum vapor deposition or sputtering. This completes the formation of the light-emitting element layer 6.

Next, the sealing layer 8 is formed (step S18). When the sealing layer 8 contains an organic sealing film, this organic sealing film may be formed by applying an organic sealing material. In addition, when the sealing layer 8 contains an inorganic sealing film, this inorganic sealing film may be formed by, for example, CVD. The sealing layer 8 is hence formed, sealing the light-emitting element layer 6.

Then, the glass substrate may be lifted off, functional films may be attached, and other steps may be performed as needed, to complete the manufacture of the display device 2. The functional films include, for example, a polarizer film, a sensor film with a touch sensor panel function, a protective film, and an antireflective film.

### Forming Light-Emitting Layer

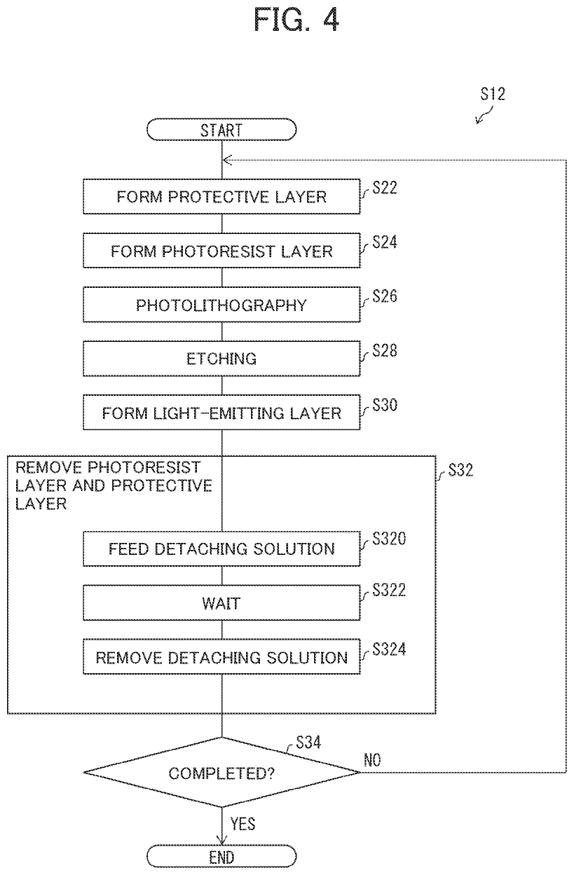

FIG. 4 is a schematic flow chart representing an exemplary step of forming the light-emitting layer 24 (step S12) in accordance with the present embodiment.

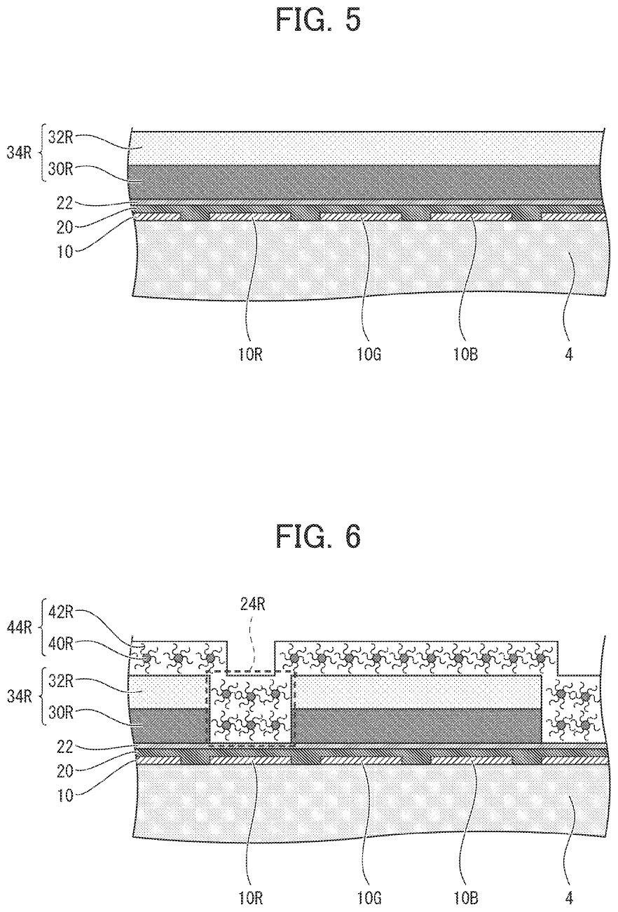

Each of FIGS. 5 to 15 is a schematic cross-sectional view of an exemplary step of forming the light-emitting layer 24 (step S12) in accordance with the present embodiment.

For a simple description, the following will only describe a case where the red light-emitting layer 24R (first light-emitting layer), the green light-emitting layer 24G (second light-emitting layer), and the blue light-emitting layer 24B (third light-emitting layer) are formed in this order at a distance from each other by lift-off, with reference to drawings.

Given such a description, a person skilled in the art will easily understand other cases.

### Forming Red Light-Emitting Layer

Referring to FIGS. 4 and 5, in step S12, first, a red protective layer 30R (protective layer) is formed on the hole transport layer 22 (step S22), and a red photoresist layer 32R (resist layer) is formed on the red protective layer 30R (step S24). As a result of step S22 and step S24, a red sacrifice layer 34R (first sacrifice layer) containing the red protective layer 30R and the red photoresist layer 32R is formed.

The red protective layer 30R is made of, for example, an acrylic resin, a polyvinylpyrrolidone (PVP) resin, a polyvinyl alcohol (PVA) resin, or a polyethylene oxide (PEO) resin. The red photoresist layer 32R may be made of, for example, a photosensitive acrylic resin or a photosensitive novolac resin.

The material for the red photoresist layer 32R, when in contact with the hole transport layer 22, could degrade the hole transport layer 22. Therefore, the red protective layer 30R is provided covering the hole transport layer 22 to prevent the red photoresist layer 32R from coming into contact with the hole transport layer 22.

Referring to FIGS. 4 and 6, next, the red photoresist layer 32R is patterned by photolithography so as to remove parts of the red photoresist layer 32R (step S26). Specifically, at least those parts of the red photoresist layer 32R which correspond to the anodes 10R of the red light-emitting elements 6R are removed. In step S26, the red photoresist layer 32R is exposed to light using a photomask and developed using a development solution.

Next, the red protective layer 30R is patterned by etching using the red photoresist layer 32R as a protective mask so as to remove parts of the red photoresist layer 32R (step S28). Specifically, at least those parts of the red photoresist layer 32R which correspond to the anodes 10R of the red light-emitting elements 6R are removed. The etching in step S28 may be either wet etching or dry etching. The etching in step S28 is preferably wet etching using the development solution used in step S26 to reduce the manufacturing cost and steps.

As a result of step S26 and step S28, parts of the red sacrifice layer 34R are removed to expose the hole transport layer 22 corresponding to the anodes 10R of the red light-emitting elements 6R. Specifically, at least those parts of the red photoresist layer 32R which correspond to the anodes 10R are removed.

Next, a red light-emitting layer 44R (first light-emitting layer) is formed on the red photoresist layer 32R and the hole transport layer 22 (step S30). The red light-emitting layer 44R contains red light-emitting, red quantum dots 40R (first quantum dots) and red ligands 42R (first ligands) coordinated to the red quantum dots 40R.

The red quantum dots 40R are degraded when they come into contact with the material for the red photoresist layer 32R. Those parts of the red light-emitting layer 44R which remain as the red light-emitting layer 24R after the patterning reside on the hole transport layer 22, whereas those parts of the red light-emitting layer 44R which are removed by the patterning reside on the red photoresist layer 32R. As described here, the red quantum dots 40R contained in the patterned, red light-emitting layer 24R do not come into contact with the red photoresist layer 32R.

The red ligands 42R cover the surfaces of the red quantum dots 40R, thereby protecting the surfaces of the red quantum dots 40R.

Next, the red light-emitting layer 44R is patterned by removing the red sacrifice layer 34R using a red detaching solution 54R (first detaching solution) in accordance with the present embodiment (step S32).

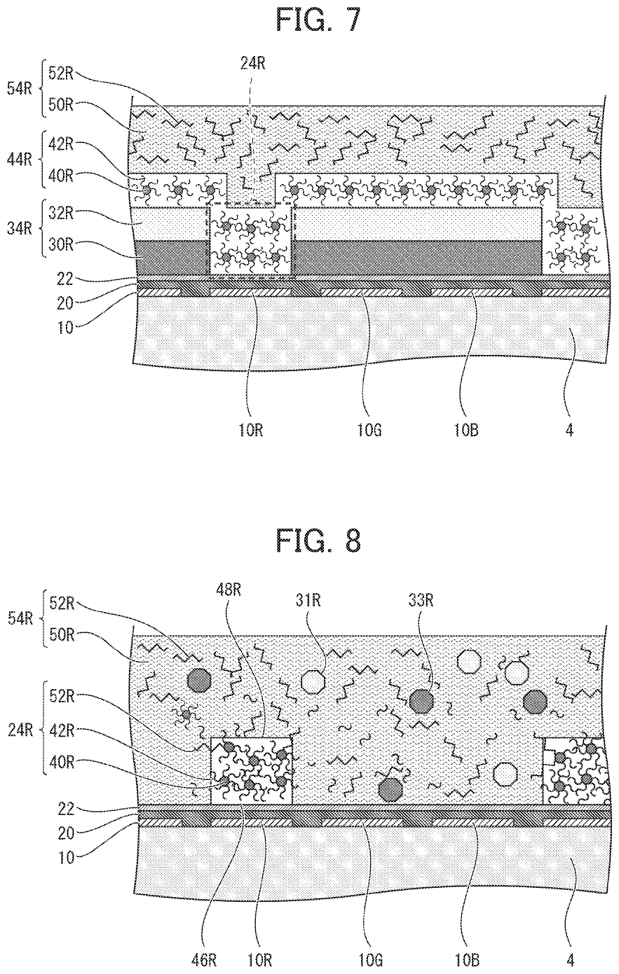

Referring to FIGS. 4 and 7, in step S32, first, the red detaching solution 54R in accordance with the present embodiment is fed to the red light-emitting layer 44R (step S320). In step S320, for example, the red detaching solution 54R is applied or dispensed onto the red light-emitting layer 44R. The red detaching solution 54R in accordance with the present embodiment is a solution prepared by adding red addition ligands 52R (second ligands) that differ from the red ligands 42R to a known detaching solution 50R. The red addition ligands 52R preferably can be coordinated to the red quantum dots 40R.

The known detaching solution 50R is a solution that can move through the red light-emitting layer 44R and dissolve the red sacrifice layer 34R. The known detaching solution 50R is, for example, an organic solvent containing, for example, acetone, PGMEA, PGME, or DMSO. Therefore, the red detaching solution 54R in accordance with the present embodiment can also move through the red light-emitting layer 44R and dissolve the red sacrifice layer 34R.

If only the known detaching solution 50R is fed to the red light-emitting layer 44R, the red ligands 42R can be readily eluted from the red light-emitting layer 44R to the known detaching solution 50R. This is because the red ligands 42R have a higher concentration in the red light-emitting layer 44R than in the known detaching solution 50R. The red ligands 42R have a concentration of 0 or approximately 0 in the known detaching solution 50R. Then, the red ligands 42R decrease in the red light-emitting layer 44R, exposing the surfaces of the red quantum dots 40R. In particular, since the red ligands 42R are eluted through a top face 48R and side faces of the red light-emitting layer 44R, the surfaces of the red quantum dots 40R that reside on the top face 48R and side faces of the red light-emitting layer 44R and in their vicinity are exposed.

In contrast, when the red detaching solution 54R in accordance with the present embodiment is fed to the red light-emitting layer 44R, the red addition ligands 52R in the red detaching solution 54R reduce the elution of the red ligands 42R. Therefore, the surfaces of the red quantum dots 40R are covered, and sufficiently protected, by the red ligands 42R. Conversely, the red addition ligands 52R in accordance with the present embodiment are selected so as to reduce the elution of the red ligands 42R from the red light-emitting layer 44R to the red detaching solution 54R.

For instance, when the red ligands 42R are organic molecules or organic ions having coordinating functional groups that can be coordinated to the red quantum dots 40R, the red addition ligands 52R are selected from the group consisting of organic molecules and organic ions having the same coordinating functional groups as the red quantum dots 40R. The coordinating functional groups are, for example, droxyl groups, aldehyde groups, carboxyl groups, carbonyl groups, ether groups, amino groups, thiol groups, or phosphine groups.

For instance, when the red ligands 42R are elemental halogen-containing inorganic ions, the red addition ligands 52R are selected from other elemental halogen-containing inorganic ions. Elemental halogen includes fluorine (F), chlorine (Cl), bromine (Br), and iodine (I).

For instance, when the red ligands 42R are elemental chalcogen-containing inorganic ions, the red addition ligands 52R are selected from other elemental chalcogen-containing inorganic ions. Elemental chalcogen includes oxygen (O), sulfur(S), selenium (Se), tellurium (Te), and polonium (Po).

In addition, when the red addition ligands 52R can be coordinated to the red quantum dots 40R, the red addition ligands 52R can bond to the surfaces of the red quantum dots 40R in place of the red ligands 42R. Therefore, the surfaces of the red quantum dots 40R are covered, and more sufficiently protected, by the red ligands 42R and/or the red addition ligands 52R.

Referring to FIGS. 4 and 8, next, the object is left to sit so that the red detaching solution 54R can permeate the red light-emitting layer 44R and dissolve the red sacrifice layer 34R (step S322). In step S322, the object is preferably left to sit, for example, for 30 seconds or longer so that the red detaching solution 54R can sufficiently permeate. In step S322, the object is preferably left to sit, for example, for not longer than 300 seconds to prevent the red detaching solution 54R from adversely affecting any one or more of the red light-emitting layer 24R, the hole transport layer 22, and the hole injection layer 20.

In step S322, the red detaching solution 54R dissolves the red sacrifice layer 34R. Hence, those parts of the red light-emitting layer 44R which are formed on the red sacrifice layer 34R are lifted off. Then, those parts of the red light-emitting layer 44R which are formed on the hole transport layer 22 remain as the red light-emitting layer 24R. Meanwhile, the dissolved material for the red sacrifice layer 34R and the lifted-off material for the red light-emitting layer 44R are extricated into the red detaching solution 54R. The dissolved material for the red sacrifice layer 34R contains a material 31R for the red protective layer 30R and a material 33R for the red photoresist layer 32R.

If only the known detaching solution 50R is fed to the red light-emitting layer 44R, the surfaces of the red quantum dots 40R are exposed as described earlier. Therefore, the material 33R for the red photoresist layer 32R readily comes into contact with the red quantum dots 40R, thereby likely causing degradation of the red quantum dots 40R in the red light-emitting layer 24R.

In contrast, when the red detaching solution 54R in accordance with the present embodiment is fed to the red light-emitting layer 44R, the surfaces of the red quantum dots 40R are covered by the red ligands 42R and/or the red addition ligands 52R as described earlier. Therefore, the material 33R for the red photoresist layer 32R will unlikely come into contact with the red quantum dots 40R, thereby unlikely causing degradation of the red quantum dots 40R.

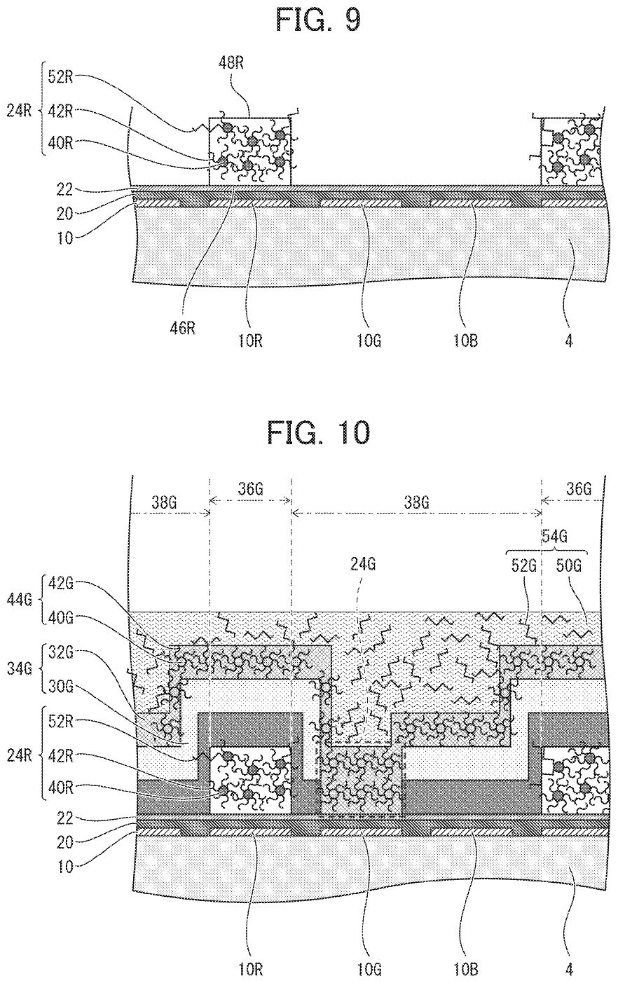

Referring to FIGS. 4 and 9, next, the red detaching solution 54R is removed (step S324). The dissolved material for the red sacrifice layer 34R and the lifted-off material for the red light-emitting layer 44R are removed along with the red detaching solution 54R.

As described in the foregoing, the red light-emitting layer 44R is patterned, thereby forming the patterned, red light-emitting layer 24R (first light-emitting layer) on the hole transport layer 22. The patterned, red light-emitting layer 24R contains the red quantum dots 40R and the red ligands 42R. In addition, when the red addition ligands 52R can be coordinated to the red quantum dots 40R, the patterned, red light-emitting layer 24R may further contain the red addition ligands 52R.

The red ligands 42R, in step S32, move from the surface of the red light-emitting layer 44R or the red light-emitting layer 24R to the red detaching solution 54R. Therefore, when the red ligands 42R are not uniformly distributed in the red light-emitting layer 24R, the red ligands 42R have a higher concentration on a bottom face 46R (interface on the first electrode side) of the red light-emitting layer 24R and in its vicinity than on the top face 48R (interface on the second electrode side) of the red light-emitting layer 24R and in its vicinity. Meanwhile, the red addition ligands 52R, in step S32, penetrate the red light-emitting layer 44R or the red light-emitting layer 24R through the surface of the red light-emitting layer 44R or the red light-emitting layer 24R. Therefore, when the red addition ligands 52R are not uniformly distributed in the red light-emitting layer 24R, the red addition ligands 52R have a lower concentration on the bottom face 46R of the red light-emitting layer 24R and in its vicinity than on the top face 48R of the red light-emitting layer 24R and in its vicinity.

Referring to FIG. 4, subsequent to step S32, it is determined whether or not the entire light-emitting layer 24 has been completely formed (step S34). Then, since the entire light-emitting layer 24 is yet to be completely formed (No), the series of steps including steps S22 to S34 is repeated.

### Forming Green Light-Emitting Layer

Referring to FIGS. 4 and 10, subsequent to step S34, a green protective layer 30G is formed on the red light-emitting layer 24R and the hole transport layer 22 (step S22), and a green photoresist layer 32G is formed on the green protective layer 30G (step S24). As a result of step S22 and step S24, a green sacrifice layer 34G (second sacrifice layer) containing the green protective layer 30G and the green photoresist layer 32G is formed. The green sacrifice layer 34G includes: an overlapping region 36G (first region) overlapping the red light-emitting layer 24R; and a non-overlapping region 38G (second region) not overlapping the red light-emitting layer 24R.

The green protective layer 30G may be made of, for example, an acrylic resin, a polyvinylpyrrolidone (PVP) resin, a polyvinyl alcohol (PVA) resin, or a polyethylene oxide (PEO) resin. The green protective layer 30G and the red protective layer 30R may be made of either the same material or different materials. The green photoresist layer 32G is made of, for example, a photosensitive acrylic resin or a photosensitive novolac resin. The green photoresist layer 32G and the red photoresist layer 32R may be made of either the same material or different materials.

The material for the green photoresist layer 32G degrades the red quantum dots 40R and/or the hole transport layer 22 when the material comes into contact with the red quantum dots 40R and/or the hole transport layer 22. Therefore, the green protective layer 30G, covering the red light-emitting layer 24R and the hole transport layer 22, is provided to prevent the green photoresist layer 32G from coming into contact with the red quantum dots 40R and the hole transport layer 22.

Next, the green photoresist layer 32G is patterned by photolithography so as to remove at least parts of the green photoresist layer 32G (step S26). Specifically, at least those parts of the green photoresist layer 32G which correspond to the anodes 10G of the green light-emitting elements 6G are removed. In step S26, the green photoresist layer 32G is exposed to light using a photomask and developed using a development solution.

Next, the green protective layer 30G is patterned by etching using the green photoresist layer 32G as a protective mask so as to remove at least parts of the green photoresist layer 32G (step S28). Specifically, at least those parts of the green photoresist layer 32G which correspond to the anodes 10G of the green light-emitting elements 6G are removed. The etching in step S28 may be either wet etching or dry etching. The etching in step S28 is preferably wet etching using the development solution used in step S26 to reduce the manufacturing cost and steps.

As a result of step S26 and step S28, at least parts of the non-overlapping region 38G of the green sacrifice layer 34G are removed to expose the hole transport layer 22 corresponding to the anodes 10G of the green light-emitting elements 6G. Specifically, at least those parts of the non-overlapping region 38G of the green sacrifice layer 34G which correspond to the anodes 10G of the green light-emitting elements 6G are removed.

Next, a green light-emitting layer 44G (second light-emitting layer) is formed on the green photoresist layer 32G and the hole transport layer 22 (step S30). The green light-emitting layer 44G contains green light-emitting, green quantum dots 40G (second quantum dots) and green ligands 42G coordinated to the green quantum dots 40G.

The green quantum dots 40G are degraded when they come into contact with the material for the green photoresist layer 32G. Those parts of the green light-emitting layer 44G which remain as the green light-emitting layer 24G after the patterning reside on the hole transport layer 22, whereas those parts of the green light-emitting layer 44G which are removed by the patterning reside on the green photoresist layer 32G. As described here, the green quantum dots 40G contained in the patterned, green light-emitting layer 24G do not come into contact with the green photoresist layer 32G.

The green ligands 42G cover the surfaces of the green quantum dots 40G, thereby protecting the surfaces of the green quantum dots 40G.

Next, the green light-emitting layer 44G is patterned by removing the green sacrifice layer 34G using a green detaching solution 54G (second detaching solution) in accordance with the present embodiment (step S32).

In step S32, first, the green detaching solution 54G in accordance with the present embodiment is fed to the green light-emitting layer 44G (step S320). In step S320, for example, the green detaching solution 54G is applied or dispensed onto the green light-emitting layer 44G. The green detaching solution 54G in accordance with the present embodiment is a solution prepared by adding green addition ligands 52G (third ligands) that differ from the green ligands 42G to a known detaching solution 50G. The green addition ligands 52G preferably can be coordinated to the green quantum dots 40G. Alternatively or additionally, the green addition ligands 52G may be capable of being coordinated to the red quantum dots 40R.

The known detaching solution 50G is a solution that can move through the green light-emitting layer 44G and dissolve the green sacrifice layer 34G. The known detaching solution 50G is, for example, an organic solvent containing, for example, acetone, PGMEA, PGME, or DMSO. The known detaching solution 50G and the known detaching solution 50R may be either the same substance or different substances. Therefore, the green detaching solution 54G in accordance with the present embodiment can also move through the green light-emitting layer 44G and dissolve the green sacrifice layer 34G.

If only the known detaching solution 50G is fed to the green light-emitting layer 44G, the green ligands 42G can be readily eluted from the green light-emitting layer 44G to the known detaching solution 50G. This is because the green ligands 42G have a higher concentration in the green light-emitting layer 44G than in the known detaching solution 50G. The green ligands 42G have a concentration of 0 or approximately 0 in the known detaching solution 50G. Then, the green ligands 42G decrease in the green light-emitting layer 44G, exposing the surfaces of the green quantum dots 40G. In particular, since the green ligands 42G are eluted through a top face 48G and side faces of the green light-emitting layer 44G, the surfaces of the green quantum dots 40G that reside on the top face 48G and side faces of the green light-emitting layer 44G and in their vicinity are exposed.

Meanwhile, when the green detaching solution 54G in accordance with the present embodiment is fed to the green light-emitting layer 44G, the green addition ligands 52G in the green detaching solution 54G reduce the elution of the green ligands 42G. Therefore, the surfaces of the green quantum dots 40G are covered, and sufficiently protected, by the green ligands 42G. Conversely, the green addition ligands 52G in accordance with the present embodiment are selected so as to reduce the elution of the green ligands 42G from the green light-emitting layer 44G to the green detaching solution 54G. In addition, when the green addition ligands 52G can be coordinated to the green quantum dots 40G, the green addition ligands 52G can bond to the surfaces of the green quantum dots 40G instead of the green ligands 42G. Therefore, the surfaces of the green quantum dots 40G are covered, and more sufficiently protected, by the green ligands 42G and/or the green addition ligands 52G.

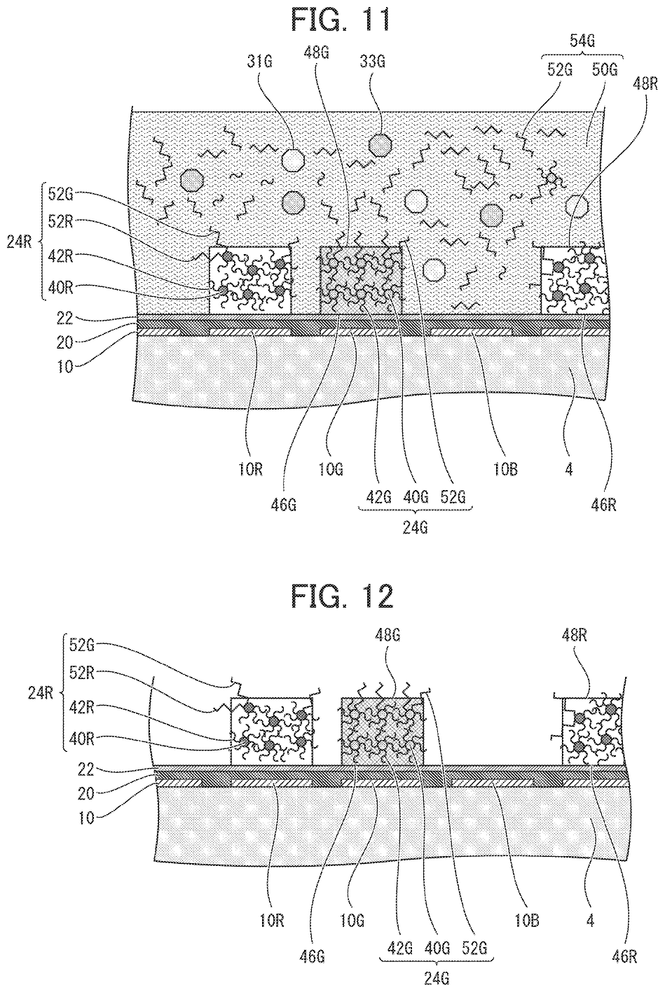

Referring to FIGS. 4 and 11, next, the object is left to sit so that the green detaching solution 54G can permeate the green light-emitting layer 44G and dissolve the green sacrifice layer 34G (step S322). In step S322, the object is preferably left to sit, for example, for 30 seconds or longer so that the green detaching solution 54G can sufficiently permeate. In step S322, the object is preferably left to sit, for example, for not longer than 300 seconds to prevent the green detaching solution 54G from adversely affecting any one or more of the red light-emitting layer 24R, the green light-emitting layer 24G, the hole transport layer 22, and the hole injection layer 20.

In step S322, the green detaching solution 54G dissolves the green sacrifice layer 34G. Hence, those parts of the green light-emitting layer 44G which are formed on the green sacrifice layer 34G are lifted off. Then, the dissolved material for the green sacrifice layer 34G and the lifted-off material for the green light-emitting layer 44G are extricated into the green detaching solution 54G. The dissolved material for the green sacrifice layer 34G contains a material 31G for the green protective layer 30G and a material 33G for the green photoresist layer 32G.

If only the known detaching solution 50G is fed to the green light-emitting layer 44G, the surfaces of the green quantum dots 40G are expose as described earlier. Therefore, the material 33G for the green photoresist layer 32G readily comes into contact with the green quantum dots 40G, thereby likely causing degradation of the green quantum dots 40G in the green light-emitting layer 44G.

Meanwhile, when the green detaching solution 54G in accordance with the present embodiment is fed to the green light-emitting layer 44G, the surfaces of the green quantum dots 40G are covered by the green ligands 42G and/or the green addition ligands 52G as described earlier. Therefore, the material 33G for the green photoresist layer 32G will unlikely come into contact with the green quantum dots 40G, thereby unlikely causing degradation of the green quantum dots 40G.

Referring to FIGS. 4 and 12, next, the green detaching solution 54G is removed (step S324). The dissolved material for the green sacrifice layer 34G and the lifted-off material for the green light-emitting layer 44G are removed along with the green detaching solution 54G.

As described in the foregoing, the green light-emitting layer 44G is patterned, thereby forming the patterned, green light-emitting layer 24G on the hole transport layer 22. The patterned, green light-emitting layer 24G contains the green quantum dots 40G and the green ligands 42G. In addition, when the green addition ligands 52G can be coordinated to the green quantum dots 40G, the patterned, green light-emitting layer 24G may further contain the green addition ligands 52G.

The green ligands 42G, in step S32, move from the surface of the green light-emitting layer 44G or the green light-emitting layer 24G to the green detaching solution 54G. Therefore, when the green ligands 42G are not uniformly distributed in the green light-emitting layer 24G, the green ligands 42G have a higher concentration on a bottom face 46G of the green light-emitting layer 24G and its vicinity than on the top face 48G of the green light-emitting layer 24G and its vicinity. Meanwhile, the green addition ligands 52G, in step S32, penetrate the green light-emitting layer 44G or the green light-emitting layer 24G through the surface of the green light-emitting layer 44G or the green light-emitting layer 24G. Therefore, when the green addition ligands 52G are not uniformly distributed in the green light-emitting layer 24G, the green addition ligands 52G have a lower concentration on the bottom face 46G of the green light-emitting layer 24G and its vicinity than on the top face 48G of the green light-emitting layer 24G and its vicinity.

In addition, when the green addition ligands 52G can be coordinated to the red quantum dots 40R, the red light-emitting layer 24R may further contain the green addition ligands 52G after the green sacrifice layer 34G is removed. The green addition ligands 52G, in step S32, penetrate the red light-emitting layer 24R through the surface of the red light-emitting layer 24R. Therefore, when the green addition ligands 52G are not uniformly distributed in in the red light-emitting layer 24R, the green addition ligands 52G have a lower concentration on the bottom face 46R of the red light-emitting layer 24R and its vicinity than on the top face 48R of the red light-emitting layer 24R and its vicinity.

Referring to FIG. 4, subsequent to step S32, it is determined whether or not the entire light-emitting layer 24 has been completely formed (step S34). Then, since the entire light-emitting layer 24 is yet to be completely formed (No), the series of steps including steps S22 to S34 is repeated.

### Forming Blue Light-Emitting Layer

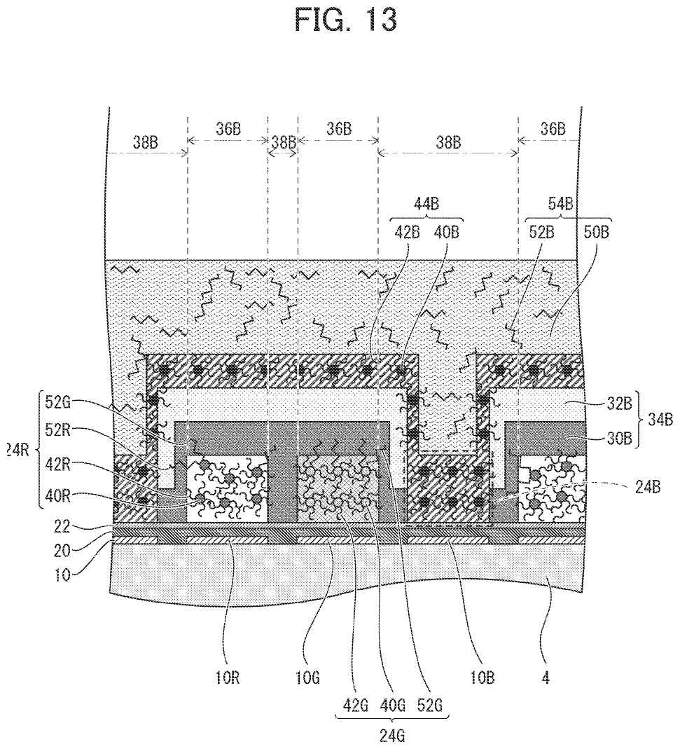

Referring to FIGS. 4 and 13, subsequent to step S34, a blue protective layer 30B is formed on the green light-emitting layer 24G, the red light-emitting layer 24R, and the hole transport layer 22 (step S22), and a blue photoresist layer 32B is formed on the blue protective layer 30B (step S24). As a result of step S22 and step S24, a blue sacrifice layer 34B (third sacrifice layer) containing the blue protective layer 30B and the blue photoresist layer 32B is formed. The blue sacrifice layer 34B includes: an overlapping region 36B (third region) overlapping either one or both of the red light-emitting layer 24R and the green light-emitting layer 24G; and a non-overlapping region 38B (fourth region) overlapping neither the red light-emitting layer 24R nor the green light-emitting layer 24G.

The blue protective layer 30B is made of, for example, an acrylic resin, a polyvinylpyrrolidone (PVP) resin, a polyvinyl alcohol (PVA) resin, or a polyethylene oxide (PEO) resin. The blue protective layer 30B and the green protective layer 30G and/or the red protective layer 30R may be made of either the same material or different materials. The blue photoresist layer 32B is made of, for example, a photosensitive acrylic resin or a photosensitive novolac resin. The blue photoresist layer 32B and the green photoresist layer 32G and/or the red photoresist layer 32R may be made of either the same material or different materials.

The material for the blue photoresist layer 32B degrades the green quantum dots 40G, the red quantum dots 40R, and/or the hole transport layer 22 when the material comes into contact with the green quantum dots 40G, the red quantum dots 40R, and/or the hole transport layer 22. Therefore, the blue protective layer 30B, covering the red light-emitting layer 24R, the green light-emitting layer 24G, and the hole transport layer 22, is provided to prevent the blue photoresist layer 32B from coming into contact with the green quantum dots 40G, the red quantum dots 40R, and the hole transport layer 22.

Next, the blue photoresist layer 32B is patterned by photolithography so as to remove parts of the blue photoresist layer 32B (step S26). Specifically, at least those parts of the blue photoresist layer 32B which correspond to the anodes 10B of the blue light-emitting elements 6B are removed. In in step S26, the blue photoresist layer 32B is exposed to light using a photomask and development using a development solution.

Next, the blue protective layer 30B is patterned by etching using the blue photoresist layer 32B as a protective mask so as to remove parts of the blue photoresist layer 32B (step S28). Specifically, at least those parts of the blue photoresist layer 32B which correspond to the anodes 10B of the blue light-emitting elements 6B are removed. The etching in step S28 may be either wet etching or dry etching. The etching in step S28 is preferably wet etching using the development solution used in step S26 to reduce the manufacturing cost and steps.

As a result of step S26 and step S28, at least parts of the non-overlapping region 38B of the blue sacrifice layer 34B are removed to expose the hole transport layer 22 corresponding to the anodes 10B of the blue light-emitting elements 6B. Specifically, at least those parts of the non-overlapping region 38B of the blue sacrifice layer 34B which correspond to the anodes 10B of the blue light-emitting elements 6B are removed.

Next, a blue light-emitting layer 44B (third light-emitting layer) is formed on the blue photoresist layer 32B and the hole transport layer 22 (step S30). The blue light-emitting layer 44B contains blue light-emitting, blue quantum dots 40B (third quantum dots) and blue ligands 42B coordinated to the blue quantum dots 40B.

The blue quantum dots 40B are degraded when they come into contact with the material for the blue photoresist layer 32B. Those parts of the blue light-emitting layer 44B which remain as the blue light-emitting layer 24B after the patterning reside on the hole transport layer 22, whereas those parts the blue light-emitting layer 44B removed by the patterning reside on the blue photoresist layer 32B. As described here, the blue quantum dots 40B contained in the patterned, blue light-emitting layer 24B do not come into contact with the blue photoresist layer 32B.

The blue ligands 42B covers the surfaces of the blue quantum dots 40B, thereby protecting the surfaces of the blue quantum dots 40B.

Next, the blue light-emitting layer 44B is patterned by removing the blue sacrifice layer 34B using a blue detaching solution 54B (third detaching solution) in accordance with the present embodiment (step S32).

In step S32, first, the blue detaching solution 54B in accordance with the present embodiment is fed to the blue light-emitting layer 44B (step S320). In step S320, for example, the blue detaching solution 54B is applied or dispensed onto the blue light-emitting layer 44B. The blue detaching solution 54B in accordance with the present embodiment is a solution prepared by adding blue addition ligands 52B (fourth ligands) that differ from the blue ligands 42B to a known detaching solution 50B. The blue addition ligands 52B preferably can be coordinated to the blue quantum dots 40B. Alternatively or additionally, the blue addition ligands 52B may be capable of being coordinated to either or both of the red quantum dots 40R and the green quantum dots 40G.

The known detaching solution 50B is a solution that can move through the blue light-emitting layer 44B and dissolve the blue sacrifice layer 34B. The known detaching solution 50B is, for example, an organic solvent containing, for example, acetone, PGMEA, PGME, or DMSO. The known detaching solution 50B and the known detaching solutions 50R, 50G may be either the same substance or different substances. Therefore, the blue detaching solution 54B in accordance with the present embodiment can also move through the blue light-emitting layer 44B and dissolve the blue sacrifice layer 34B.

If the known detaching solution 50B is fed to the blue light-emitting layer 44B, the blue ligands 42B can be readily eluted from the blue light-emitting layer 44B to the known detaching solution 50B. This is because the blue ligands 42B have a higher concentration in the blue light-emitting layer 44B than in the known detaching solution 50B. The blue ligands 42B have a concentration of 0 or approximately 0 in the known detaching solution 50B. Then, the blue ligands 42B decrease in the blue light-emitting layer 44B, exposing the surfaces of the blue quantum dots 40B. In particular, since the blue ligands 42B are eluted through a top face 48B and side faces of the blue light-emitting layer 44B, the surfaces of the blue quantum dots 40B that reside on the top face 48B and side faces of the blue light-emitting layer 44B and their vicinity are exposed.

Meanwhile, when the blue detaching solution 54B in accordance with the present embodiment is fed to the blue light-emitting layer 44B, the blue addition ligands 52B in the blue detaching solution 54B reduce the elution of the blue ligands 42B. Therefore, the surfaces of the blue quantum dots 40B are covered, and sufficiently protected, by the blue ligands 42B. Conversely, the green addition ligands 52G in accordance with the present embodiment are selected so as to reduce the elution of the blue ligands 42B from the blue light-emitting layer 44B to the blue detaching solution 54B. In addition, when the blue addition ligands 52B can be coordinated to the blue quantum dots 40B, the blue addition ligands 52B can bond to the surfaces of the blue quantum dots 40B instead of the blue ligands 42B. Therefore, the surfaces of the blue quantum dots 40B are covered, and more sufficiently protected, by the blue ligands 42B and/or the blue addition ligands 52B.

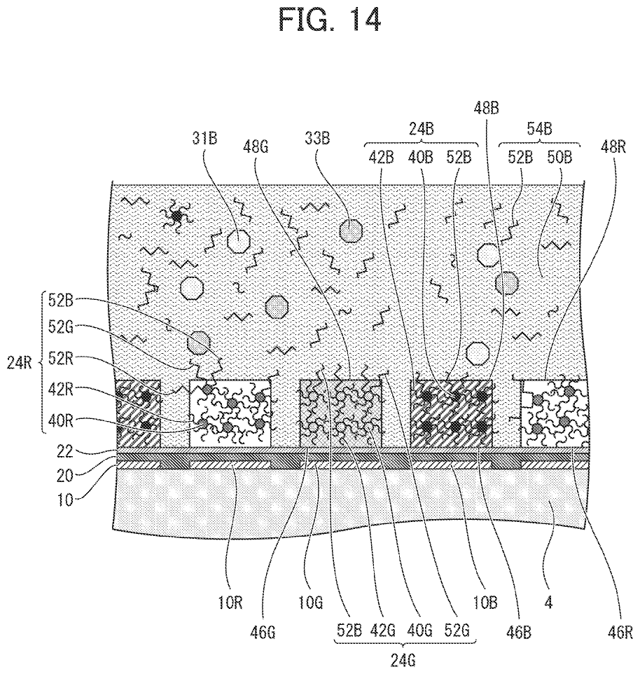

Referring to FIGS. 4 and 14, next, the object is left to sit so that the blue detaching solution 54B can permeate the blue light-emitting layer 44B and dissolve the blue sacrifice layer 34B (step S322). In step S322, the object is preferably left to sit, for example, for 30 seconds or longer so that the blue detaching solution 54B can sufficiently permeate. In step S322, the object is preferably left to sit, for example, for not longer than 300 seconds to prevent the blue detaching solution 54B from adversely affecting any one of the red light-emitting layer 24R, the green light-emitting layer 24G, the blue light-emitting layer 24B, the hole transport layer 22, and the hole injection layer 20.

In step S322, the blue detaching solution 54B dissolves the blue sacrifice layer 34B. Hence, those parts of the blue light-emitting layer 44B which are formed on the blue sacrifice layer 34B are lifted off. Then, the dissolved material for the blue sacrifice layer 34B and the lifted-off material for the blue light-emitting layer 44B are extricated into the blue detaching solution 54B. The dissolved material for the blue sacrifice layer 34B contains a material 31B for the blue protective layer 30B and a material 33B for the blue photoresist layer 32B.

If the known detaching solution 50B is fed to the blue light-emitting layer 44B, the surfaces of the blue quantum dots 40B are exposed as described earlier. Therefore, the material 33B for the blue photoresist layer 32B readily comes into contact with the blue quantum dots 40B, thereby likely causing degradation of the blue quantum dots 40B in the blue light-emitting layer 44B.

Meanwhile, when the blue detaching solution 54B in accordance with the present embodiment is fed to the blue light-emitting layer 44B, the surfaces of the blue quantum dots 40B are covered by the blue ligands 42B and/or the blue addition ligands 52B as described earlier. Therefore, the material 33B for the blue photoresist layer 32B will unlikely come into contact with the blue quantum dots 40B, thereby unlikely causing degradation of the blue quantum dots 40B.

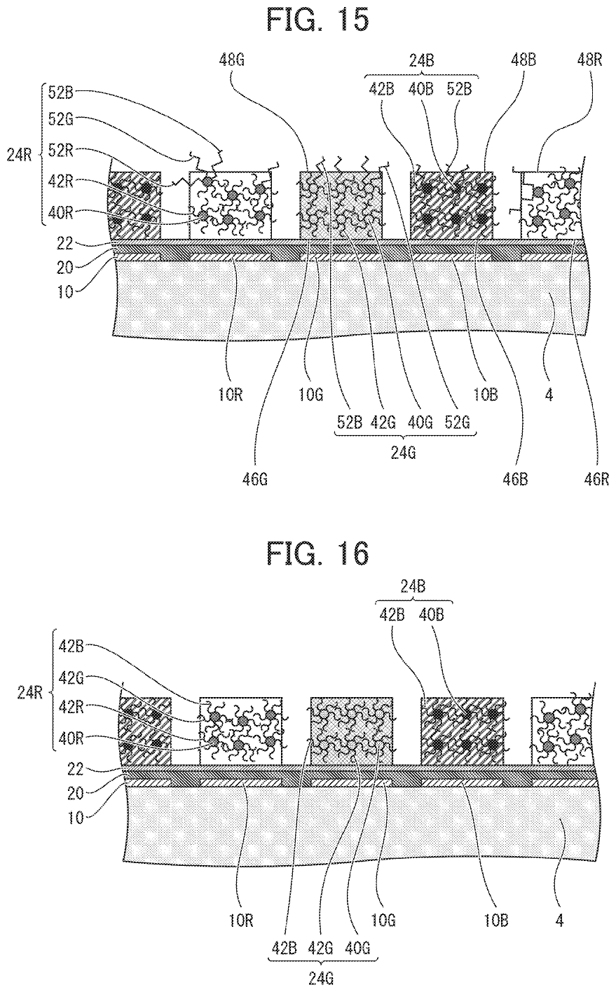

Referring to FIGS. 4 and 15, next, the blue detaching solution 54B is removed (step S324). The dissolved material for the blue sacrifice layer 34B and the lifted-off material for the blue light-emitting layer 44B are removed along with the blue detaching solution 54B.

As described in the foregoing, the blue light-emitting layer 44B is patterned, thereby forming the patterned, blue light-emitting layer 24B on the hole transport layer 22. The patterned, blue light-emitting layer 24B contains the blue quantum dots 40B and the blue ligands 42B. In addition, when the blue addition ligands 52B can be coordinated to the blue quantum dots 40B, the patterned, blue light-emitting layer 24B may further contain the blue addition ligands 52B.

The blue ligands 42B, in step S32, move from the surface of the blue light-emitting layer 44B or the blue light-emitting layer 24B to the blue detaching solution 54B. Therefore, when the blue ligands 42B are not uniformly distributed in the blue light-emitting layer 24B, the blue ligands 42B have a higher concentration on a bottom face 46B of the blue light-emitting layer 24B and its vicinity than on the top face 48B of the blue light-emitting layer 24B and its vicinity. Meanwhile, the blue addition ligands 52B, in step S32, penetrate the blue light-emitting layer 44B or the blue light-emitting layer 24B through the surface of the blue light-emitting layer 44B or the blue light-emitting layer 24B. Therefore, when the blue addition ligands 52B are not uniformly distributed in the blue light-emitting layer 24B, the blue addition ligands 52B have a lower concentration on the bottom face 46B of the blue light-emitting layer 24B and its vicinity than on the top face 48B of the blue light-emitting layer 24B and its vicinity.

In addition, when the blue addition ligands 52B can be coordinated to the red quantum dots 40R, the red light-emitting layer 24R may further contain the blue addition ligands 52B after the blue sacrifice layer 34B is removed. Likewise, when the blue addition ligands 52B can be coordinated to the green quantum dots 40G, the green light-emitting layer 24G may further contain the blue addition ligands 52B after the blue sacrifice layer 34B is removed. The blue addition ligands 52B, in step S32, penetrate the red light-emitting layer 24R and/or the green light-emitting layer 24G through the surface of the red light-emitting layer 24R and/or the green light-emitting layer 24G. Therefore, when the blue addition ligands 52B are not uniformly distributed in the red light-emitting layer 24R and/or the green light-emitting layer 24G, the blue addition ligands 52B have a lower concentration on the bottom face 46R, 46G of the red light-emitting layer 24R and/or the green light-emitting layer 24G and its vicinity than on the top face 48R, 48G of the red light-emitting layer 24R and/or the green light-emitting layer 24G and its vicinity.

Referring to FIG. 4, subsequent to step S32, it is determined whether or not the entire light-emitting layer 24 has been completely formed (step S34). Then, since the entire light-emitting layer 24 has been completely formed (Yes), step S12 is terminated.

As described in the foregoing, according to the method and structure in accordance with the present embodiment, the red light-emitting layer 24R, the green light-emitting layer 24G, and the blue light-emitting layer 24B are protected from lack of ligands and degradation due to resist material respectively. That in turn advantageously improves the life and reliability of the display device 2.

### Ligands

When the red ligands 42R, the green ligands 42G, the blue ligands 42B, the red addition ligands 52R, the green addition ligands 52G, and the blue addition ligands 52B are organic ligands, these ligands preferably respectively contain alkyl groups to remain dispersed in the solvent. Specifically, each ligand is preferably structured to contain at least one of alkyl thiol, alkyl amine, alkyl carboxylate, and alkylated phosphorus.

When the red ligands 42R, the green ligands 42G, the blue ligands 42B, the red addition ligands 52R, the green addition ligands 52G, and the blue addition ligands 52B are inorganic ligands, these ligands preferably respectively contain halide ions to improve coordinating ability (ease in coordination) to quantum dots. Specifically, each of the ligands is preferably structured to contain at least one of a tetrabutyl ammonium halide such as TBAF, TBACl, TBABr, or TBAI and a zinc halide such as ZnF₂, ZnCl₂, ZnBr₂, or Znl₂.

Here, TBA denotes tetrabutyl ammonium, Zn denotes zinc, F denotes fluorine, Cl denotes chlorine, Br denotes bromine, and I denotes iodine.

As described earlier, in the present embodiment, the red addition ligands 52R differ from the red ligands 42R. This means that the red ligands 42R and the red addition ligands 52R are made of different materials. Likewise, the green addition ligands 52G differ from the green ligands 42G. This means that the green ligands 42G and the green addition ligands 52G are made of different materials. Likewise, the blue addition ligands 52B differ from the blue ligands 42B. This means that the blue ligands 42B and the blue addition ligands 52B are made of different materials. For example, when the red ligands 42R are dodecane thiol, the red addition ligands 52R are not dodecane thiol.

In addition, in the present embodiment, the red ligands 42R, the green ligands 42G, and the blue ligands 42B may be respectively either the same or different. Additionally, the red addition ligands 52R, the green addition ligands 52G, and the blue addition ligands 52B may be respectively the same or different. Additionally, the red ligands 42R may be either the same or different from the green addition ligands 52G and/or the blue addition ligands 52B. Additionally, the green ligands 42G may be either the same or different from the red addition ligands 52R and/or the blue addition ligands 52B. Additionally, the blue ligands 42B may be either the same or different from the red addition ligands 52R and/or the green addition ligands 52G.

When the red addition ligands 52R can be coordinated to the red quantum dots 40R, the red addition ligands 52R preferably have lower electron transportability than do the red ligands 42R. Specifically, the red addition ligands 52R preferably have a longer chain shape than do the red ligands 42R. As described earlier, the red addition ligands 52R have a higher concentration on the top face 48R of the red light-emitting layer 24R and its vicinity than on the bottom face 46R of the red light-emitting layer 24R and its vicinity. In the present embodiment, the bottom face 46R is the anode 10 side, and the top face 48R is the cathode 16 side. In addition, light-emitting elements typically tend to operate with excessive electrons. Therefore, in this case, the charge-carrier balance of the red light-emitting elements 6R can be adjusted suitably by reducing the injection of electrons from the cathode 16 to the red light-emitting layer 24R.

Throughout the present disclosure, “X having a longer chain shape than Y” indicates that each substance constituting X and Y has a long-chain structure such as an alkyl group and that the substance constituting X has a longer molecular length than the substance constituting Y.

Likewise, when the green addition ligands 52G can be coordinated to the red quantum dots 40R and/or the green quantum dots 40G, the green addition ligands 52G preferably have lower electron transportability than do the red ligands 42R and/or the green ligands 42G. Specifically, the green addition ligands 52G preferably have a longer chain shape than do the red ligands 42R and/or the green ligands 42G. Hence, the charge-carrier balance of the red light-emitting elements 6R and/or the green light-emitting elements 6G can be adjusted suitably by reducing the injection of electrons from the cathode 16 to the red light-emitting layer 24R and/or the green light-emitting layer 24G.

Likewise, additionally, when the blue addition ligands 52B can be coordinated to the red quantum dots 40R, the green quantum dots 40G, and/or the blue quantum dots 40B, the blue addition ligands 52B preferably have lower electron transportability than do the red ligands 42R, the green ligands 42G, and/or the blue ligands 42B. Specifically, the blue addition ligands 52B preferably have a longer chain shape than do the red ligands 42R, the green ligands 42G, and/or the blue ligands 42B. Hence, the charge-carrier balance of the red light-emitting elements 6R, the green light-emitting elements 6G, and/or the blue light-emitting elements 6B can be adjusted suitably by reducing the injection of electrons from the cathode 16 to the red light-emitting layer 24R, the green light-emitting layer 24G, and/or the blue light-emitting layer 24B.

### Non-Uniform Distribution of Ligands

As described above, ligands might not be uniformly distributed in the light-emitting layer 24. The presence/absence and degree of this non-uniform distribution may be demonstrated by various means. For a simple description, the red light-emitting layer 24R is taken as an example where the red addition ligands 52R can be coordinated to the red quantum dots 40R.

For instance, in an SEM observation, when the red ligands 42R appear different from the red addition ligands 52R and when the red quantum dots 40R to which the red ligands 42R are coordinated appear different from the red quantum dots 40R to which the red addition ligands 52R are coordinated, the cross-section of the red light-emitting layer 24R is imaged or observed by SEM.

In addition, for example, when the red ligands 42R are readily adsorbed by an adsorbent whereas the red addition ligands 52R are hardly adsorbed by the same adsorbent, a sample collected from the vicinity of the bottom face 46R of the red light-emitting layer 24R (hereinafter, “upper sample”) and a sample collected from the vicinity of the top face 48R of the red light-emitting layer 24R (hereinafter, “lower sample”) are analyzed by column chromatography filled with the adsorbent. Specifically, the upper and lower samples of the red light-emitting layer 24R are dissolved in a solvent, each solution is poured into the column, a solution coming out of the column is retrieved, and the concentration of the red addition ligands 52R in each retrieved solution is measured and compared.

In addition, for example, when the red ligands 42R are readily dissolved in a solvent whereas the red addition ligands 52R are hardly dissolved by the same solvent, the upper and lower samples of the red light-emitting layer 24R are dissolved and filtered in the solvent, and the concentration of the red addition ligands 52R in each filtrate is measured and compared.

In addition, for example, when the substance constituting the red ligands 42R do not contain an element or functional group whereas the substance constituting the red addition ligands 52R contains the same element or functional group, the upper and lower samples of the red light-emitting layer 24R are analyzed using an X-ray analysis apparatus. Specifically, the magnitude of the peak frequency corresponding to the element or functional group in each sample is measured and compared.

In addition, for example, when the mass number of the substance constituting the red ligands 42R differs from the mass number of the substance constituting the red addition ligands 52R, the upper and lower samples of the red light-emitting layer 24R are analyzed using a mass spectrometer (MS).

### Embodiment 2

The following will describe another embodiment of the disclosure. Note that for convenience of description, members of the present embodiment that have the same function as members of the preceding embodiment are indicated by the same reference numerals, and description thereof is not repeated.

The green addition ligands 52G in accordance with the present embodiment are characterized by being different from the red ligands 42R contained in the red light-emitting layer 24R and being selected so as to reduce the elution of the red ligands 42R from the red light-emitting layer 24R to the green detaching solution 54G. In addition, the green addition ligands 52G in accordance with the present embodiment preferably can be coordinated to the red quantum dots 40R. The green addition ligands 52G in accordance with the present embodiment may be either the same or different from the green ligands 42G contained in the green light-emitting layer 44G.

Likewise, the blue addition ligands 52B in accordance with the present embodiment are characterized by (1) being different from the red ligands 42R contained in the red light-emitting layer 24R and being selected so as to reduce the elution of the red ligands 42R from the red light-emitting layer 24R to the blue detaching solution 54B and/or (2) being different from the green ligands 42G contained in the green light-emitting layer 24G and being selected so as to reduce the elution of the green ligands 42G from the green light-emitting layer 24G to the blue detaching solution 54B. In addition, the blue addition ligands 52B in accordance with the present embodiment preferably can be coordinated to the red quantum dots 40R and/or the green quantum dots 40G. The blue addition ligands 52B in accordance with the present embodiment may be either the same or different from the blue ligands 42B contained in the blue light-emitting layer 44B.

The method in accordance with the present embodiment is the same as the method in accordance with aforementioned Embodiment 1, except for those points described above.

### Forming Light-Emitting Layer

For a simple description, the following description will focus solely on cases where the blue addition ligands 52B satisfy both (1) and (2).

Referring to FIG. 11, in step S322 in step S12 for forming the green light-emitting layer 24G, the green detaching solution 54G dissolves the green sacrifice layer 34G. Then, the material 33G for the green photoresist layer 32G is extricated into the green detaching solution 54G, and the green detaching solution 54G is in direct contact with the red light-emitting layer 24R.

If only the known detaching solution 50G is fed to the green light-emitting layer 44G, the red ligands 42R can be readily eluted from the red light-emitting layer 24R to the known detaching solution 50G. This is because the red ligands 42R have a higher concentration in the red light-emitting layer 24R than in the known detaching solution 50G. The red ligands 42R have a concentration of 0 or approximately 0 in the known detaching solution 50G. Then, the red ligands 42R decrease in the red light-emitting layer 24R, exposing the surfaces of the red quantum dots 40R. In particular, since the red ligands 42R are eluted through the top face 48R and side faces of the red light-emitting layer 24R, the surfaces of the red quantum dots 40R that reside on the top face 48R and side faces of the red light-emitting layer 24R and in their vicinity are exposed. Therefore, the material 33G for the green photoresist layer 32G readily comes into contact with the red quantum dots 40R, and the red quantum dots 40R contained in the red light-emitting layer 24R are likely to be degraded.

In contrast, when the green detaching solution 54G in accordance with the present embodiment is fed to the green light-emitting layer 44G, the green addition ligands 52G reduce the elution of the red ligands 42R. Therefore, the surfaces of the red quantum dots 40R are covered, and sufficiently protected by, the red ligands 42R. In addition, when the green addition ligands 52G can be coordinated to the red quantum dots 40R, the green addition ligands 52G can bond to the surfaces of the red quantum dots 40R instead of the red ligands 42R. Therefore, the surfaces of the red quantum dots 40R are covered, and more sufficiently protected, by the red ligands 42R and/or the green addition ligands 52G. Therefore, the material 33G for the green photoresist layer 32G will unlikely come into contact with the red quantum dots 40R, thereby unlikely causing degradation of the red quantum dots 40R.

Referring to FIG. 14, in step S322 in step S12 for forming the blue light-emitting layer 24B, the blue detaching solution 54B dissolves the blue sacrifice layer 34B. Then, the material 33B for the blue photoresist layer 32B is extricated into the blue detaching solution 54B, and the blue detaching solution 54B is in direct contact with the red light-emitting layer 24R and the green light-emitting layer 24G.

Therefore, likewise, if only the known detaching solution 50B is fed to the blue light-emitting layer 44B, the red quantum dots 40R contained in the red light-emitting layer 24R and the green quantum dots 40G contained in the green light-emitting layer 24G will likely be degraded. In contrast, when the blue detaching solution 54B in accordance with the present embodiment is fed to the blue light-emitting layer 44B, the red quantum dots 40R contained in the red light-emitting layer 24R and the green quantum dots 40G contained in the green light-emitting layer 24G will unlikely be degraded.

As described in the foregoing, according to the method and structure in accordance with the present embodiment, the red light-emitting layer 24R and the green light-emitting layer 24G are protected from lack of ligands and degradation due to resist material respectively. That in turn advantageously improves the life and reliability of the display device 2.

### Ligands

The green addition ligands 52G differ from the red ligands 42R in the present embodiment as described earlier. This means that the red ligands 42R and the green addition ligands 52G are made of different materials. Likewise, the blue addition ligands 52B differ from either or both of the red ligands 42R and the green ligands 42G. This means that either or both of the red ligands 42R and the green ligands 42G are made of a different material than the blue addition ligands 52B. For example, when the red ligands 42R are oleic acid, the green addition ligands 52G are not oleic acid.

In addition, in the present embodiment, the red ligands 42R, the green ligands 42G, and the blue ligands 42B may be either the same or different respectively. In addition, the red addition ligands 52R, the green addition ligands 52G, and the blue addition ligands 52B may be either the same or different respectively. In addition, the red ligands 42R may be either the same or different from the red addition ligands 52R. In addition, the green ligands 42G may be either the same or different from the red addition ligands 52R and/or the green addition ligands 52G. In addition, the blue ligands 42B may be either the same or different from the red addition ligands 52R, the green addition ligands 52G, and/or the blue addition ligands 52B.

### Embodiment 3

The following will describe another embodiment of the disclosure. Note that for convenience of description, members of the present embodiment that have the same function as members of the preceding embodiments are indicated by the same reference numerals, and description thereof is not repeated.

FIG. 16 is a schematic cross-sectional view of an exemplary step of forming the light-emitting layer 24 in accordance with the present embodiment (step S12).

The red detaching solution 54R in accordance with the present embodiment is a solution prepared by adding the red ligands 42R to the known detaching solution 50R. The red ligands 42R in the red detaching solution 54R reduce the elution of the red ligands 42R from the red light-emitting layer 44R and the red light-emitting layer 24R to the red detaching solution 54R. In addition, the red ligands 42R in the red detaching solution 54R can be coordinated to the red quantum dots 40R.

The green detaching solution 54G in accordance with the present embodiment is a solution prepared by adding the green ligands 42G to the known detaching solution 50G. The green ligands 42G in the green detaching solution 54G reduce the elution of the green ligands 42G from the green light-emitting layer 44G and the green light-emitting layer 24G to the green detaching solution 54G. In addition, the green ligands 42G in the green detaching solution 54G can be coordinated to the green quantum dots 40G. In addition, the green ligands 42G in the green detaching solution 54G may be capable of being coordinated to the red quantum dots 40R.

The blue detaching solution 54B in accordance with the present embodiment is a solution prepared by adding the blue ligands 42B to the known detaching solution 50B. The blue ligands 42B in the blue detaching solution 54B reduce the elution of the blue ligands 42B from the blue light-emitting layer 44B and the blue light-emitting layer 24B to the blue detaching solution 54B. In addition, the blue ligands 42B in the blue detaching solution 54B can be coordinated to the blue quantum dots 40B. In addition, the blue ligands 42B in the blue detaching solution 54B may be capable of being coordinated to the red quantum dots 40R and/or the green quantum dots 40G.

The method in accordance with the present embodiment is the same as the method in accordance with aforementioned Embodiment 1, except for those points described above. Therefore, the method and structure in accordance with the present embodiment achieve the same effects as the method and structure in accordance with aforementioned Embodiment 1.

Referring to FIG. 16, the red light-emitting layer 24R in accordance with the present embodiment contains the red quantum dots 40R and the red ligands 42R. In addition, when the green ligands 42G can be coordinated to the red quantum dots 40R, the red light-emitting layer 24R may further contain the green ligands 42G after the green sacrifice layer 34G is removed. In addition, when the blue ligands 42B can be coordinated to the red quantum dots 40R, the red light-emitting layer 24R may further contain the blue ligands 42B after the blue sacrifice layer 34B is removed. The green ligands 42G and/or the blue ligands 42B, in step S32, penetrate the red light-emitting layer 24R through the surface of the red light-emitting layer 24R. Therefore, when the green ligands 42G and/or the blue ligands 42B are not uniformly distributed in the red light-emitting layer 24R, the green ligands 42G and/or the blue ligands 42B have a lower concentration on the bottom face of the red light-emitting layer 24R and its vicinity than on the top face of the red light-emitting layer 24R and its vicinity.

The green light-emitting layer 24G in accordance with the present embodiment contains the green quantum dots 40G and the green ligands 42G. In addition, when the blue ligands 42B can be coordinated to the green quantum dots 40G, the green light-emitting layer 24G may further contain the blue ligands 42B after the blue sacrifice layer 34B is removed. The blue ligands 42B, in step S32, penetrate the green light-emitting layer 24G through the surface of the green light-emitting layer 24G. Therefore, when the blue ligands 42B are not uniformly distributed in the green light-emitting layer 24G, the blue ligands 42B have a lower concentration on the bottom face of the green light-emitting layer 24G and its vicinity than on the top face of the green light-emitting layer 24G and its vicinity.

The blue light-emitting layer 24B in accordance with the present embodiment contains the blue quantum dots 40B and the blue ligands 42B.

### Example 1

The following will describe a working example of Embodiment 3 of the present disclosure.

Step S2 through step S18 (see FIG. 3) were sequentially performed.

In step S12, the series of steps including step S22 through step S32 (see FIG. 4) was performed only once.

In step S22, the red protective layer 30R containing an acrylic resin was formed on the hole transport layer 22.

In step S24, the red photoresist layer 32R containing a photosensitive acrylic resin layer was formed on the red protective layer 30R.

In step S30, the red light-emitting layer 44R containing the red quantum dots 40R and the red ligands 42R was formed on the hole transport layer 22 and the red photoresist layer 32R. The red quantum dots 40R had an InP/ZnS core-shell structure. The red quantum dots 40R, unless degraded, can absorb light with a wavelength of approximately 365 nm and emit light with a wavelength of approximately 640 nm. The red ligands 42R were dodecane thiol.

In step S32, the red detaching solution 54R prepared by adding dodecane thiol to the known detaching solution 50R was fed to the red light-emitting layer 44R. The known detaching solution 50R was PGME. The dodecane thiol in the red detaching solution 54R had a concentration of 0.3 mol/L.

The display device 2 of Example 1 was formed as described in the foregoing.

### Example 2

The display device 2 of Example 2 was formed in the same manner as the display device 2 of Example 1.

### Comparative Example 1

In step S32, the known detaching solution 50R containing no red ligands 42R was fed to the red light-emitting layer 44R.

Otherwise, the display device 2 of Comparative Example 1 was formed in the same manner as the display device 2 of Example 1.

### Comparative Example 2

The display device 2 of Comparative Example 2 was formed in the same manner as the display device 2 of Comparative Example 1.

### Measuring Photoluminescence Life

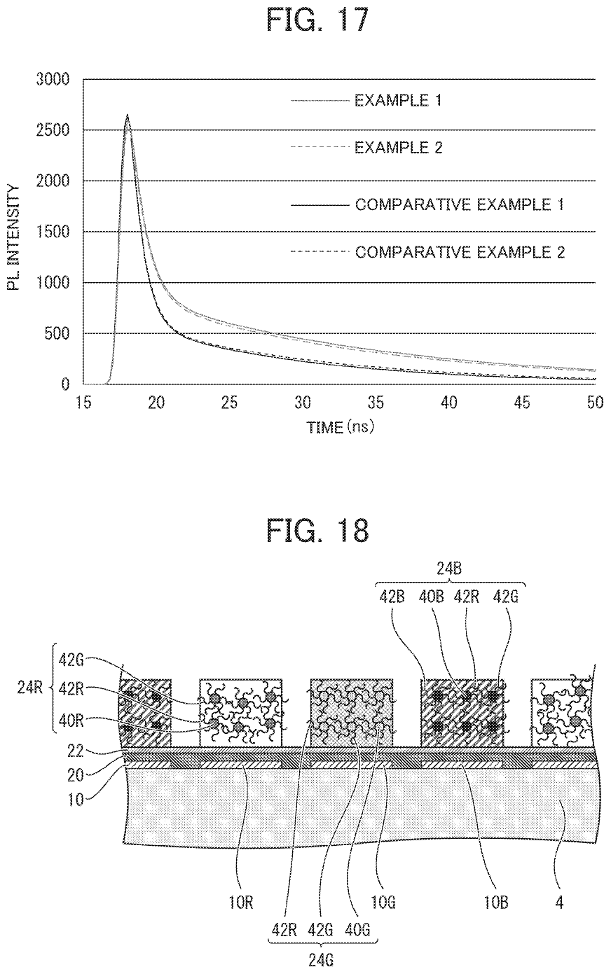

FIG. 17 is a diagram showing a graph representing temporal changes in the photoluminescence intensities of the display devices 2 of Examples 1 and 2 and Comparative Examples 1 and 2.

Light with a wavelength of approximately 365 nm was projected at a fixed intensity to the display areas DA of the display devices 2 of Examples 1 and 2 and Comparative Examples 1 and 2, and the intensity of the light with a wavelength of approximately 640 nm emitted by the display areas DA was measured.

Referring to FIG. 17, the temporal changes in photoluminescence intensity generally match between Examples 1 and 2, and the temporal changes in photoluminescence intensity generally match between Comparative Examples 1 and 2. In contrast, the temporal changes in photoluminescence intensity in Examples 1 and 2 obviously differ from the temporal changes in photoluminescence intensity in Comparative Examples 1 and 2. This indicates that the differences between the combination of Examples 1 and 2 and the combination of Comparative Examples 1 and 2 are not manufacturing errors. Therefore, significant performance difference is achieved by adding ligands to the detaching solution.

At and after approximately 18 ns, the photoluminescence intensity decays more slowly in Examples 1 and 2 than in Comparative Examples 1 and 2, and the photoluminescence intensity is higher in Examples 1 and 2 than in Comparative Examples 1 and 2. This indicates that the red quantum dots 40R have a longer photoluminescence life in Examples 1 and 2 than in Comparative Examples 1 and 2. Therefore, since the life and reliability of the light-emitting elements can be improved by adding ligands to the detaching solution, the life and reliability of the display device 2 can be improved.

### Embodiment 4

The following will describe another embodiment of the disclosure. Note that for convenience of description, members of the present embodiment that have the same function as members of the preceding embodiments are indicated by the same reference numerals, and description thereof is not repeated.

FIG. 18 is a schematic cross-sectional view of an exemplary step of forming the light-emitting layer 24 in accordance with the present embodiment (step S12).

The green detaching solution 54G in accordance with the present embodiment is a solution prepared by adding the red ligands 42R to the known detaching solution 50G. The red ligands 42R in the green detaching solution 54G reduce the elution of the red ligands 42R from the red light-emitting layer 24R to the green detaching solution 54G. In addition, the red ligands 42R in the green detaching solution 54G can be coordinated to the red quantum dots 40R. In addition, the red quantum dots 40R in the green detaching solution 54G may be capable of being coordinated to the green quantum dots 40G.

The blue detaching solution 54B in accordance with the present embodiment is a solution prepared by adding the red ligands 42R and/or the green ligands 42G to the known detaching solution 50B. The red ligands 42R in the blue detaching solution 54B reduce the elution of the red ligands 42R from the red light-emitting layer 24R to the blue detaching solution 54B. In addition, the red ligands 42R in the blue detaching solution 54B can be coordinated to the red quantum dots 40R. In addition, the red ligands 42R in the blue detaching solution 54B may be capable of being coordinated to the green quantum dots 40G and/or the blue quantum dots 40B. Likewise, the green ligands 42G in the blue detaching solution 54B reduce the elution of the green ligands 42G from the green light-emitting layer 24G to the blue detaching solution 54B. In addition, the green ligands 42G in the blue detaching solution 54B can be coordinated to the green quantum dots 40G. In addition, the green ligands 42G in the blue detaching solution 54B may be capable of being coordinated to the red quantum dots 40R and/or the blue quantum dots 40B.

The method in accordance with the present embodiment is the same as the method in accordance with aforementioned Embodiment 2, except for those points described above. Therefore, the method and structure in accordance with the present embodiment achieve the same effects as the method and structure in accordance with aforementioned Embodiment 2.

Referring to FIG. 18, the red light-emitting layer 24R in accordance with the present embodiment contains the red quantum dots 40R and the red ligands 42R. In addition, when the green ligands 42G can be coordinated to the red quantum dots 40R, and the blue detaching solution 54B contains the green ligands 42G, the red light-emitting layer 24R may further contain the green ligands 42G after the blue sacrifice layer 34B is removed. The green ligands 42G, in step S32, penetrate the red light-emitting layer 24R through the surface of the red light-emitting layer 24R. Therefore, when the green ligands 42G are not uniformly distributed in the red light-emitting layer 24R, the green ligands 42G have a lower concentration on the bottom face of the red light-emitting layer 24R and its vicinity than on the top face of the red light-emitting layer 24R and its vicinity.

The green light-emitting layer 24G in accordance with the present embodiment contains the green quantum dots 40G and the green ligands 42G. In addition, when the red ligands 42R can be coordinated to the green quantum dots 40G, and the blue detaching solution 54B contains the red ligands 42R, the green light-emitting layer 24G may further contain the red ligands 42R after the blue sacrifice layer 34B is removed. The red ligands 42R, in step S32, penetrate the green light-emitting layer 24G through the surface of the green light-emitting layer 24G. Therefore, when the red ligands 42R are not uniformly distributed in the green light-emitting layer 24G, the red ligands 42R have a lower concentration on the bottom face of the green light-emitting layer 24G and its vicinity than on the top face of the green light-emitting layer 24G and its vicinity.

The blue light-emitting layer 24B in accordance with the present embodiment contains the blue quantum dots 40B and the blue ligands 42B. In addition, when the green ligands 42G can be coordinated to the blue quantum dots 40B, and the blue detaching solution 54B contains the green ligands 42G, the patterned, blue light-emitting layer 24B may further contain the green ligands 42G. In addition, when the red ligands 42R can be coordinated to the blue quantum dots 40B, and the blue detaching solution 54B contains the red ligands 42R, the patterned, blue light-emitting layer 24B may further contain the red ligands 42R. The red ligands 42R and/or the green ligands 42G are not uniformly distributed in the blue light-emitting layer 24B, the red ligands 42R and/or the green ligands 42G have a lower concentration on the bottom face of the blue light-emitting layer 24B and its vicinity than on the top face of the blue light-emitting layer 24B and its vicinity.

### Embodiment 5

The following will describe another embodiment of the disclosure. Note that for convenience of description, members of the present embodiment that have the same function as members of the preceding embodiments are indicated by the same reference numerals, and description thereof is not repeated.

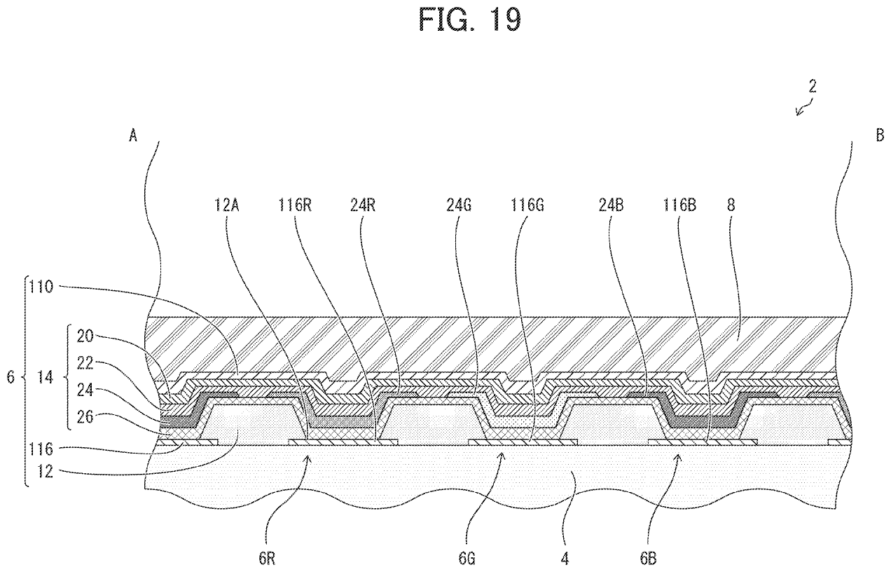

FIG. 19 is a schematic cross-sectional view of an exemplary structure of the display area DA of the display device 2 in accordance with the present embodiment.

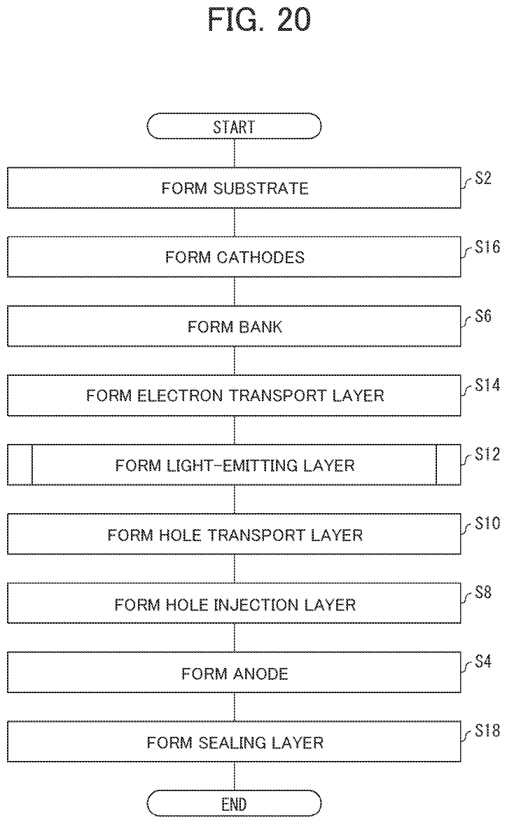

FIG. 20 is a schematic flow chart representing an exemplary method of manufacturing the display device 2 in accordance with the present embodiment.

Referring to FIG. 19, the light-emitting element layer 6 in accordance with the present embodiment includes: cathodes 116 (first electrodes) on the substrate 4; an anode 110 (second electrode) opposite the cathodes 116; the bank 12; and the active layer 14 between the anode 110 and the cathodes 116.

Here, each light-emitting element includes one of the cathodes 116 formed therein. One cathode 116 is provided in each light-emitting element, that is, insularly in each subpixel, and is alternatively referred to as a pixel electrode. The cathode 116 includes a cathode 116R for the red light-emitting element 6R, a cathode 116G for the green light-emitting element 6G, and a cathode 116B for the blue light-emitting element 6B. Meanwhile, the hole injection layer 20, the hole transport layer 22, the electron transport layer 26, and the anode 110 are each provided commonly to a plurality of light-emitting elements. The anode 110 is alternatively referred to as the common electrode.

Referring to FIG. 20, in the method of manufacturing the display device 2 in accordance with the present embodiment, first, the substrate 4 is formed (step S2), the cathodes 116 are formed (step S16), and the bank 12 is formed (step S6). Subsequently, the electron transport layer 26 is formed (step S14), the light-emitting layer 24 is formed (step S12), the hole transport layer 22 is formed (step S10), and the hole injection layer 20 is formed (step S8). Next, the anode 110 is formed (step S4), and the sealing layer 8 is formed (step S18). Then, the glass substrate may be lifted off, functional films may be attached, and other steps may be performed as needed, to complete the manufacture of the display device 2.

Therefore, the display device 2 in accordance with the present embodiment differs from the display device 2 in accordance with aforementioned Embodiment 1 in that the light-emitting element layer 6 has its order of stacking reversed. In addition, according to this, in the method of manufacturing the display device 2 in accordance with the present embodiment, the sequence of steps between step S2 and step S18 differs from the display device 2 in accordance with aforementioned Embodiment 1. The method and structure in accordance with the present embodiment are the same as the method and structure in accordance with aforementioned Embodiment 1, except for those points.

Therefore, the method and structure in accordance with the present embodiment achieve the same effects as the method and structure in accordance with aforementioned Embodiment 1.

### Ligands

When the red addition ligands 52R can be coordinated to the red quantum dots 40R, the red addition ligands 52R preferably have higher hole transportability than the red ligands 42R. Specifically, the red ligands 42R preferably have a longer chain shape than do the red addition ligands 52R. As described earlier, the red addition ligands 52R have a higher concentration on the top face the red light-emitting layer 24R and its vicinity than on the bottom face of the red light-emitting layer 24R and its vicinity. In the present embodiment, the bottom face is the cathode 116 side, and the top face is the anode 110 side. In addition, light-emitting elements typically tend to operate with excessive electrons. Therefore, in this case, the charge-carrier balance of the red light-emitting elements 6R can be adjusted suitably by increasing the injection of holes from the anode 110 to the red light-emitting layer 24R.

Likewise, when the green addition ligands 52G can be coordinated to the red quantum dots 40R and/or the green quantum dots 40G, the green addition ligands 52G preferably have higher hole transportability than do the red ligands 42R and/or the green ligands 42G. Specifically, the red ligands 42R and/or the green ligands 42G preferably have a longer chain shape than do the green addition ligands 52G. Hence, the charge-carrier balance of the red light-emitting elements 6R and/or the green light-emitting elements 6G can be adjusted suitably by increasing the injection of holes from the anode 110 to the red light-emitting layer 24R and/or the green light-emitting layer 24G.

Likewise, in addition, when the blue addition ligands 52B can be coordinated to the red quantum dots 40R, the green quantum dots 40G, and/or the blue quantum dots 40B, the blue addition ligands 52B preferably have higher hole transportability than do the red ligands 42R, the green ligands 42G, and/or the blue ligands 42B. Specifically, the red ligands 42R, the green ligands 42G, and/or the blue ligands 42B preferably have a longer chain shape than do the blue addition ligands 52B. Hence, the charge-carrier balance of the red light-emitting elements 6R, the green light-emitting elements 6G, and/or the blue light-emitting elements 6B can be adjusted suitably by increasing the injection of holes from the anode 110 to the red light-emitting layer 24R, the green light-emitting layer 24G, and/or the blue light-emitting layer 24B.

The disclosure is not limited to the description of the embodiments above and may be altered within the scope of the claims. Embodiments based on a proper combination of technical means disclosed in different embodiments are encompassed in the technical scope of the disclosure. Furthermore, new technological features can be created by combining different technical means disclosed in the embodiments.

The detaching solution in accordance with the present disclosure includes detaching solutions to which ligands are added.

The manufacturing method in accordance with the present disclosure includes a method of patterning at least one layer contained in the light-emitting layer 24 by lift-off using the detaching solution to which ligands are added. In other words, the present disclosure encompasses a manufacturing method that involves performing at least once a series of steps including: a step of forming a sacrifice layer on a charge functional layer (and if there is already formed a light-emitting layer, on this light-emitting layer); a step of exposing the charge functional layer by removing parts of the sacrifice layer; a step of forming a light-emitting layer on the sacrifice layer and the charge functional layer; and a step of patterning the light-emitting layer by removing the sacrifice layer using a detaching solution in accordance with the present embodiment.

The display device in accordance with the present disclosure includes display devices in which at least one layer contained in the light-emitting layer 24 is patterned by lift-off using the detaching solution to which ligands are added.

For instance, any two or more of Embodiments 1 to 4 may be combined. For example, in Embodiments 2 to 4, the light-emitting element layer 6 may have its order of stacking reversed, similarly to Embodiment 5. For example, any two or more of Embodiments 2 to 4 in which the light-emitting element layer 6 has its order of stacking reversed and Embodiment 5 may be combined.

1. A method of manufacturing a display device, the method comprising:
a step of forming a first sacrifice layer on a charge functional layer;
a step of exposing the charge functional layer by removing a part of the first sacrifice layer;
a step of forming a first light-emitting layer containing first quantum dots and first ligands on the first sacrifice layer and the charge functional layer; and
a step of patterning the first light-emitting layer by removing the first sacrifice layer using a first detaching solution containing second ligands.

2. The method according to claim 1, wherein the second ligands are configured to be coordinated to the first quantum dots.

3. The method according to claim 2, wherein the first light-emitting layer contains the second ligands after the first sacrifice layer is removed.

4. The method according to claim 1, wherein the first ligands and the second ligands are made of different materials.

5. The method according to claim 1, wherein the first ligands and the second ligands are made of a same material.

6. The method according to claim 1, wherein
the first ligands contain at least one of alkyl thiol, alkyl amine, alkyl carboxylic acid, and alkylated phosphorus, and
the second ligands contain at least one of alkyl thiol, alkyl amine, alkyl carboxylic acid, and alkylated phosphorus.

7. The method according to claim 1, wherein the first ligands contain at least one of tetrabutyl ammonium halide and zinc halide, and the second ligands contain at least one of tetrabutyl ammonium halide and zinc halide.

8. The method according to claim 1, wherein the first sacrifice layer includes: a protective layer on the charge functional layer; and a resist layer on the protective layer.

9. The method according to claim 1, further comprising:
a step of forming a second sacrifice layer including a first region overlapping the first light-emitting layer and a second region not overlapping the first light-emitting layer;
a step of exposing the charge functional layer by removing at least a part of the second region;
a step of forming a second light-emitting layer containing second quantum dots on the second sacrifice layer and the charge functional layer; and
a step of patterning the second light-emitting layer by removing the second sacrifice layer using a second detaching solution containing third ligands.

10. A method of manufacturing a display device, the method comprising:
a step of forming a patterned first light-emitting layer containing first quantum dots and first ligands on a charge functional layer;
a step of forming a second sacrifice layer including a first region overlapping the first light-emitting layer and a second region not overlapping the first light-emitting layer;
a step of exposing the charge functional layer by removing at least a part of the second region;
a step of forming a second light-emitting layer containing second quantum dots on the second sacrifice layer and the charge functional layer; and
a step of patterning the second light-emitting layer by removing the second sacrifice layer using a second detaching solution containing third ligands.

11. The method according to claim 9, wherein the third ligands are configured to be coordinated to the first quantum dots.

12. The method according to claim 9, wherein the first light-emitting layer contains the third ligands after the second sacrifice layer is removed.

13. The method according to claim 9, wherein the first ligands and the third ligands are made of different materials.

14. The method according to claim 9, wherein the first ligands and the third ligands are made of a same material.

15. The method according to claim 9, wherein
the first ligands contain at least one of alkyl thiol, alkyl amine, alkyl carboxylic acid, and alkylated phosphorus, and
the third ligands contain at least one of alkyl thiol, alkyl amine, alkyl carboxylic acid, and alkylated phosphorus.

16. The method according to claim 9, wherein the first ligands contain at least one of tetrabutyl ammonium halide and zinc halide, and the third ligands contain at least one of tetrabutyl ammonium halide and zinc halide.

17. The method according to claim 9, wherein the second quantum dots emit green or blue light.

18. The method according to claim 9, further comprising:
a step of forming a third sacrifice layer including: a third region overlapping either one or both of the first light-emitting layer and the second light-emitting layer; and a fourth region overlapping neither the first light-emitting layer nor the second light-emitting layer;
a step of exposing the charge functional layer by removing at least a part of the fourth region;
a step of forming a third light-emitting layer containing third quantum dots on the third sacrifice layer and the charge functional layer; and
a step of patterning the third light-emitting layer by removing the third sacrifice layer using a detaching solution containing fourth ligands.

19. The method according to claim 1, wherein the charge functional layer contains nanoparticles of a metal oxide.

20. The method according to claim 19, wherein
the charge functional layer includes a hole injection layer, and
the hole injection layer contains a nickel oxide as the metal oxide.

21-24. (canceled)
